(19) United States
(12) Patent Application Publication
(10) Pub. No.: US 2025/0299765 A1
(43) Pub. Date: Sep. 25, 2025

(54) MEMORY SYSTEM

(71) Applicant: Kioxia Corporation, Tokyo (JP)

(72) Inventors: Shogo Muto, Fujisawa Kanagawa (JP); Masanobu Shirakawa, Chigasaki Kanagawa (JP)

(73) Assignee: Kioxia Corporation, Tokyo (JP)

(21) Appl. No.: 19/041,462

(22) Filed: Jan. 30, 2025

(30) Foreign Application Priority Data
Mar. 19, 2024 (JP) 2024-043906

(51) Int. Cl. G11C 29/52; G11C 16/26; G11C 16/34

(52) U.S. Cl. CPC G11C 29/52; G11C 16/26; G11C 16/3418

(57) ABSTRACT

In one embodiment, a memory system includes a non-volatile memory including a plurality of memory cells; and a memory controller. The memory controller is configured to store first data read from the plurality of memory cells using a first voltage in a storage circuit, store second data read from a bit group including respective bits of the plurality of memory cells using a first read voltage group in a storage circuit, perform an error correction of the second data, and determine, if third data is obtained as a result of successful error correction of the second data, a second read voltage group based on the first data stored in the storage circuit, the second data, and the third data.

### CROSS-REFERENCE TO RELATED APPLICATIONS

This application is based upon and claims the benefit of priority from Japanese Patent Application No. 2024-43906, filed Mar. 19, 2024, the entire contents of which are incorporated herein by reference.

### FIELD

Embodiments described herein relate generally to a memory system.

### BACKGROUND

A memory system including a memory and a controller configured to control the memory is known. There is a demand for such a memory system to store data with high reliability.

### BRIEF DESCRIPTION OF THE DRAWINGS

FIG. 1 illustrates an example of components of a memory system and couplings of the components according to a first embodiment.

FIG. 2 illustrates components of a block of a semiconductor memory in the memory system according to the first embodiment and couplings of the components.

FIG. 3 illustrates an example of a structure of a part of a memory cell array in the memory system according to the first embodiment.

FIG. 4 illustrates an example of threshold voltage distribution and data mappings of memory cell transistors in the memory system according to the first embodiment.

FIG. 5 illustrates an example of functional blocks during operation of the memory system according to the first embodiment.

FIG. 6 illustrates a flow of an operation of the memory system according to the first embodiment.

FIG. 7 illustrates a concept of a first-type shift amount estimation by the memory system according to the first embodiment.

FIG. 8 illustrates data obtained by an operation by the memory system according to the first embodiment.

FIG. 9 illustrates a flow of an operation of the memory system according to the first embodiment.

FIG. 10 illustrates an example of data obtained during an operation of the memory system according to the first embodiment.

FIG. 11 illustrates another example of data obtained during an operation by the memory system according to the first embodiment.

FIG. 12 illustrates a concept of a second-type shift amount estimation by the memory system according to the first embodiment.

FIG. 13 illustrates a flow of an operation of the memory system according to the first embodiment.

FIGS. 14 to 19 illustrate a concept of a second- type shift amount estimation by a memory system according to a second embodiment.

FIG. 20 illustrates a flow of an operation of the memory system according to the second embodiment.

FIGS. 21 to 26 illustrate a concept of a second-type shift amount estimation by a memory system according to a modification of the second embodiment.

FIG. 27 illustrates a flow of an operation of a memory system according to a modification of the second embodiment.

FIG. 28 illustrates an example of functional blocks during operation of a memory system according to a third embodiment.

FIG. 29 illustrates a flow of an operation of the memory system according to the third embodiment.

FIG. 30 illustrates an example of synthesized page data and illustrates a concept of an operation by the memory system according to the third embodiment.

FIG. 31 illustrates a flow of an operation of the memory system according to the third embodiment.

FIG. 32 illustrates a flow of an operation of a memory system according to a modification of the third embodiment.

FIGS. 33 to 36 illustrate a concept of a first-type shift amount estimation by a memory system according to a fourth embodiment.

FIG. 37 illustrates an example of synthesized page data and illustrates a concept of an operation by a memory cell according to the fourth embodiment.

FIGS. 38 to 40 illustrates a flow of an operation of the memory system according to the fourth embodiment.

FIGS. 41 to 42 illustrates a concept of a first-type shift amount estimation by a memory system according to a second modification of the fourth embodiment.

FIG. 43 illustrates a flow of an operation of a memory system according to a fourth modification of the fourth embodiment.

### DETAILED DESCRIPTION

In one embodiment, a memory system includes a non-volatile memory including a plurality of memory cells; and a memory controller. The memory controller is configured to store first data read from the plurality of memory cells in a storage circuit. The first data is read by using a first voltage. The memory controller is configured to store second data read from a bit group including respective bits of the plurality of memory cells in a storage circuit. The second data is read by using a first read voltage group. The memory controller is configured to perform an error correction of the second data, and determine, if third data is obtained as a result of successful error correction of the second data, a second read voltage group based on the first data stored in the storage circuit, the second data, and the third data.

Embodiments will now be described with reference to the figures. In order to distinguish components having substantially the same function and configuration in an embodiment or over different embodiments from each other, an additional numeral or letter may be added to the end of each reference numeral or letter. In the following description, in an embodiment following an embodiment that is already described, different points from the already described embodiment are mainly described. The entire description of a particular embodiment applies to another embodiment unless an explicit mention is made otherwise, or an obvious elimination is involved.

Steps in the flow of a method according to an embodiment are not limited to any of the illustrated orders, and may occur in an order different from the illustrated orders and/or may occur concurrently with another step or steps.

### 1. First Embodiment

### 1. 1. Structure (Configuration)

### 1. 1. 1. Memory System

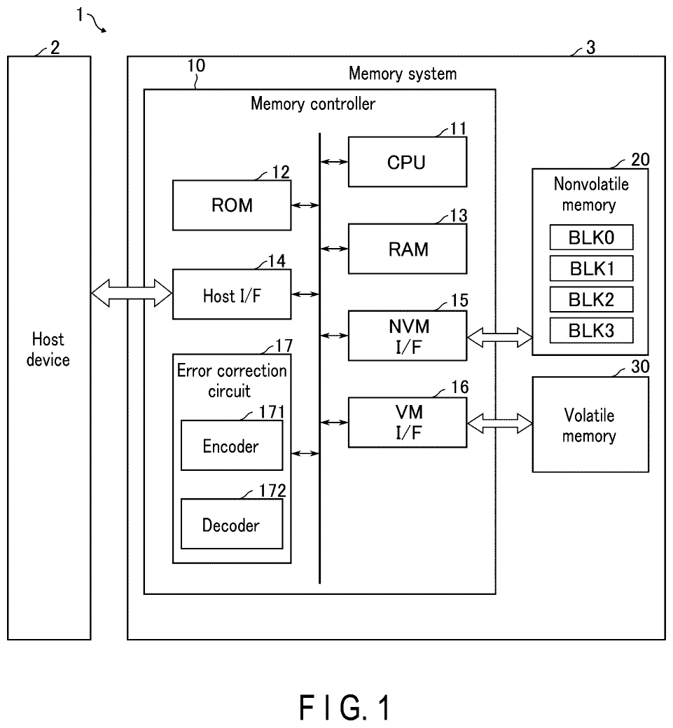

FIG. 1 illustrates an example of components of a memory system according to a first embodiment and couplings of the components. FIG. 1 illustrates a configuration of hardware.

As illustrated in FIG. 1, an information processing system 1 includes a host device 2 and a memory system 3.

The host device 2 is a device that processes data using the memory system 3. Examples of the host device 2 includes a personal computer and a sever in a data center.

The memory system 3 is a device that stores data. Examples of the memory system 3 include a memory card such as an SD™ card, and a solid state drive (SSD). The memory system 3 stores, reads, and erases data in response to a request from the host device 2. The memory system 3 may store, read, and erase data regardless of a request from the host device 2.

The memory system 3 includes a memory controller 10, a nonvolatile memory 20, and a volatile memory 30.

Examples of the nonvolatile memory 20 include a NAND flash memory. The nonvolatile memory 20 includes a plurality of blocks BLK (BLK0 to BLK3). Each block BLK includes a plurality of memory cells. Each memory cell stores data in a nonvolatile manner. In an example, a block BLK is a unit of data erasure.

Examples of the volatile memory 30 include a dynamic random-access memory (DRAM). The volatile memory 30 stores information such as information related to a read voltage that is used in reading data from the nonvolatile memory 20.

The memory controller 10 is a controller that controls the nonvolatile memory 20. Examples of the form of the memory controller 10 include an integrated circuit such as a system on a chip (SoC). The memory controller 10 controls the nonvolatile memory 20 to perform process requested by the host device 2. Specifically, the memory controller 10 writes write data in the nonvolatile memory 20 based on a write request from the host device 2. The memory controller 10 reads read data from the nonvolatile memory 20 and transmits data based on the read data based on a read request from the host device 2.

The memory controller 10 includes a central processing unit (CPU) 11, a read only memory (ROM) 12, a random access memory (RAM) 13, a host interface (host I/F) 14, a nonvolatile memory interface (NVM I/F) 15, a volatile memory interface (VM I/F) 16, and an error correction circuit 17.

The CPU 11 is a circuit that controls an overall operation of the memory controller 10. Through execution of programs stored in the ROM 12 and loaded onto the RAM 13 by the CPU 11, the memory controller 10 performs various operations. Firmware is configured to cause the CPU 11 to perform operations to be described in the embodiments and to realize functional blocks to be described in the embodiments.

The ROM 12 is a nonvolatile memory. Examples of the ROM 12 includes an electrically erasable programmable read only memory (EEPROM). The ROM 12 stores programs including firmware.

The RAM 13 is a volatile memory. The RAM 13 temporarily stores data, and stores programs stored in the ROM 12 while the memory system 3 is being supplied with a power supply. Examples of the RAM 13 include a dynamic random access memory (DRAM) and a static random access memory (SRAM). The RAM 13 also functions as a buffer memory.

The host interface 14 is an interface for the memory controller 10 to communicate with the host device 2. The host interface 14 includes hardware or a combination of hardware and software. The host interface 14 is coupled to the host device 2 via an interconnect for enabling communications according to a scheme which the memory controller 10 and the host device 2 comply with. In one example, the memory controller 10 complies with SD™ interface, serial attached small computer system interface (SAS), or peripheral component interconnect express (PCIe™).

The nonvolatile memory interface 15 is an interface for the memory controller 10 to communicate with the nonvolatile memory 20. The nonvolatile memory interface 15 includes hardware or a combination of hardware and software. The nonvolatile memory interface 15 is coupled to the nonvolatile memory 20 via an interconnect for enabling communications according to a scheme based on a type of the nonvolatile memory 20. The nonvolatile memory interface 15 transmits a command, address information, and write data to the nonvolatile memory 20, and receives read data from the nonvolatile memory 20. The nonvolatile memory interface 15 transmits various control signals for controlling the nonvolatile memory 20 to the nonvolatile memory 20.

The volatile memory interface 16 is an interface for the memory controller 10 to communicate with the volatile memory 30. The volatile memory interface 16 includes hardware or a combination of hardware and software. The volatile memory interface 16 is coupled to the volatile memory 30 via an interconnect for enabling communications according to a scheme based on a type of the volatile memory 30. In one example, the volatile memory interface complies with a DRAM interface standard.

The error correction circuit 17 includes an encoder 171 and decoder 172, and performs process for detecting and correcting an error to data that will be written in the nonvolatile memory 20 and detection and correction of an error in data read from the nonvolatile memory 20 using an error correction code (ECC). The error correction circuit 17 may be realized as an independent dedicated semiconductor chip, may be a circuit formed on a semiconductor substrate, or may be realized by the CPU 11 as a result of executing firmware. The encoder 171 generates an error correction code from data (substantial write data) to be written in the memory device 1. The error correction code thus generated from the substantial write data is added to the substantial write data, based on a scheme of generation of the error correction code. The substantial write data, and the error correction code generated from the substantial write data are written in the nonvolatile memory 20. The decoder 172 decodes the read data using the error correction code. The decoder 172 detects a fail bit in data read from the nonvolatile memory 20. A fail bit is a bit of data (including one or more bits) read from a memory cell and different from the bit of the data written into the memory cell. Upon detecting the fail bit, the decoder 172 determines a position of the fail bit, and corrects the fail bit. Examples of the correction method include hard bit decoding and soft bit decoding. Examples of hard bit decoding codes used in hard bit decoding include Bose-Chaudhuri-Hocquenghem (BCH) codes and Reed-Solomon (RS) codes. Examples of soft bit decoding codes used in soft bit decoding include low-density parity-check (LDPC) codes.

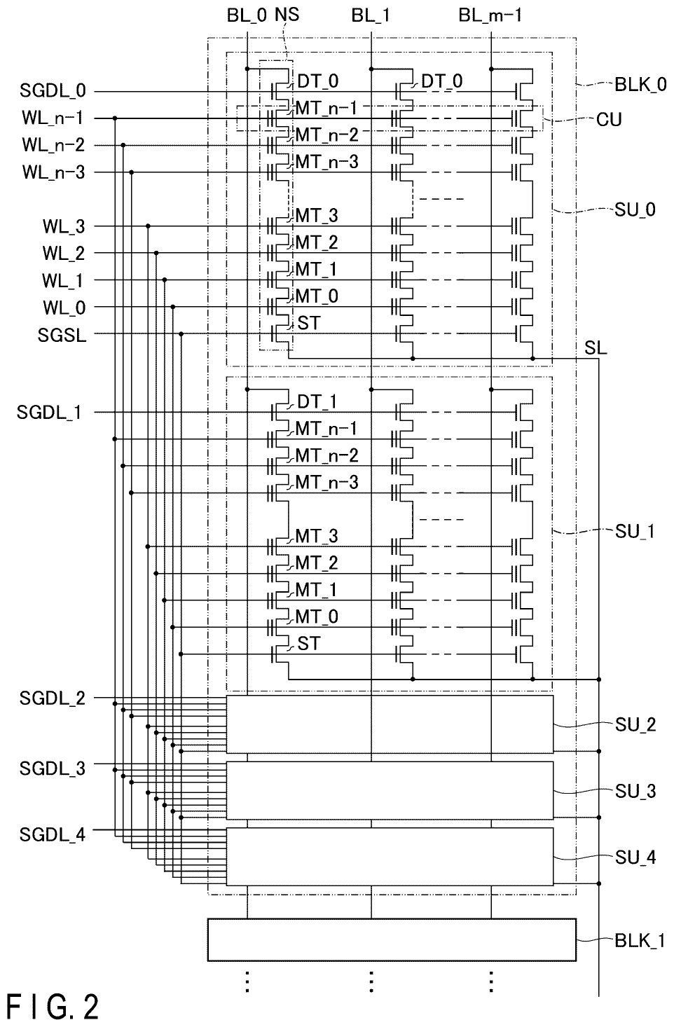

FIG. 2 illustrates components and coupling of the components of a block of the nonvolatile memory of the memory system of the first embodiment. A plurality of blocks BLK, for example, all blocks BLK, include the components and the coupling illustrated in FIG. 2.

The block BLK includes a plurality of string units SU. FIG. 2 illustrates an example of five string units SU_0 to SU_4.

As illustrated in FIG. 2, each of m-number of bit lines BL_0 to BL_m−1 is coupled, in each block BLK, to a single NAND string NS from each of string units SU_0 to SU_4, where m is a positive integer.

Each NAND string NS includes a single select gate transistor ST, n-number of cell transistors MT (MT_0 to MT_n−1), and a single select gate transistor DT (DT_0, DT_1, DT_2, DT_3, or DT_4), where n is a positive integer. Each cell transistor functions as a single memory cell. The cell transistor MT is an element that stores data in a nonvolatile manner. The cell transistor MT includes a control gate electrode or gate electrode (or, word line WL) and a charge storage film insulated from the surrounding, and stores data in a nonvolatile manner based on charge in the charge storage film. Data is written to the cell transistor MT by injecting electrons into the charge storage film.

The select gate transistors ST, cell transistors MT_0 to MT_n−1, and select gate transistor DT are coupled in series in the named order between a source line SL and a single bit line BL.

A plurality of NAND strings NS respectively coupled to a plurality of different bit lines BL configure a single string unit SU. In each string unit SU, the control gate electrodes of the cell transistors MT_0 to MT_n−1 are coupled to the word lines WL_0 to WL_n−1, respectively. A set of cell transistors MT, which share a single word line WL in one string unit SU, is called “cell unit CU”.

The select gate transistors DT_0 to DT_4 belong to the string units SU_0 to SU_4, respectively. In FIG. 2, the select gate transistors DT_2, DT_3, and DT_4 are not illustrated. The gate of the select gate transistor DT_0 of each of the NAND strings NS of the string unit SU_0 is coupled to a select gate line SGDL_0. Similarly, the gates of the select gate transistors DT_1, DT_2, DT_3, and DT_4 of the respective NAND strings NS of the string units SU_1, SU_2, SU_3, and SU_4 are coupled to select gate lines SGDL_1, SGDL_2, SGDL_3, and SGDL_4.

The gate of the select gate transistor ST is coupled to a select gate line SGSL.

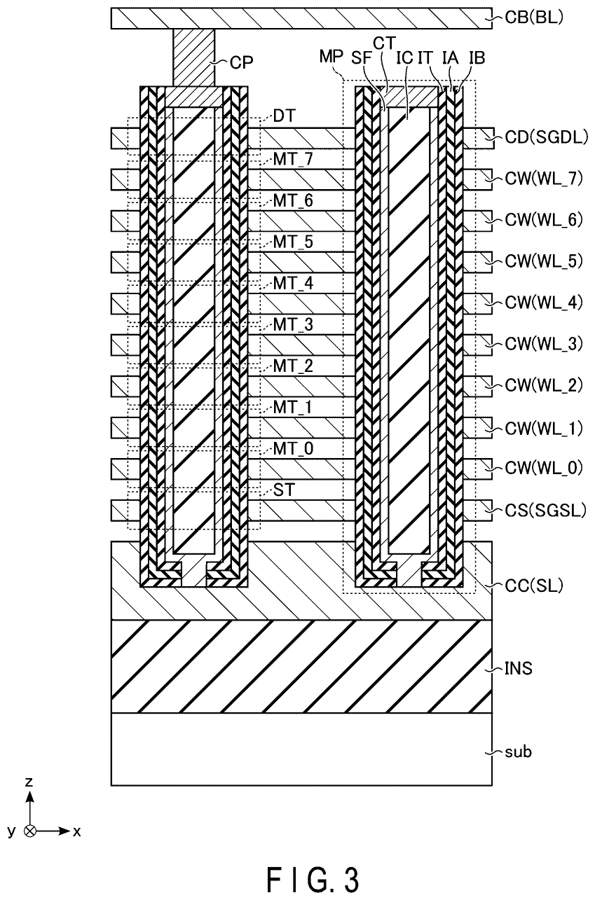

Each block BLK may have any structure as long as the circuit illustrated in FIG. 2 is implemented. As an example, each block BLK may have a structure illustrated in FIG. 3. FIG. 3 schematically illustrates an example of the structure of a part of the memory cell array of the memory system according to the first embodiment. FIG. 3 is based on an example where n is eight.

As illustrated in FIG. 3, an insulator INS is provided on an upper surface of a substrate sub. A conductor CC is provided on an upper surface of the insulator INS. The conductor CC functions as a part of the source line SL.

A single conductor CS, eight conductors CW, and a conductor CD are provided above the conductor CC. The conductors CS, CW, and CD are arranged along the z-axis at intervals in the named order and extend along the y-axis. The conductors CS, CW, and CD function as a select gate line SGSL, word lines WL_0 to WL_7, and a select gate line SGDL of each NAND string NS, respectively.

A memory pillar MP is provided above the conductor CC. The memory pillar MP penetrates the conductors CS, CW, and CD. A lower surface of the memory pillar MP is positioned in the conductor CC. The memory pillar MP includes an insulator IC, a semiconductor (layer) SF, a tunnel insulator (layer) IT, a charge storage layer IA, a block insulator (layer) IB, and a conductor (layer) CT.

The insulator IC has a columnar shape extending along the z-axis and is positioned at a center of the memory pillar MP. The semiconductor SF covers a side surface of the insulator IC. The semiconductor SF is in contact with the conductor CC at a part of a lower surface. The semiconductor SF functions as a channel region and a body of the cell transistors MT and the select gate transistors DT and ST. The channel region is a region where a channel is formed.

The tunnel insulator IT covers a side surface of the semiconductor SF. The charge storage layer IA is an insulator or a conductor, and covers a side surface of the tunnel insulator IT. The block insulator IB covers a side surface of the tunnel insulator IT.

The conductor CT covers an upper surface of the insulator IC and an upper surface of the semiconductor SF.

Upper surfaces of some conductors CT are coupled to a conductor CB via a conductive plug CP. The conductors CB extend along the x-axis and arranged along the y-axis. The conductor CB functions as a single bit line BL.

Portions of the memory pillars MP intersecting the conductors CS, CW, and CD function as the select gate transistor ST, the memory cell transistors MT, and the select gate transistor DT, respectively.

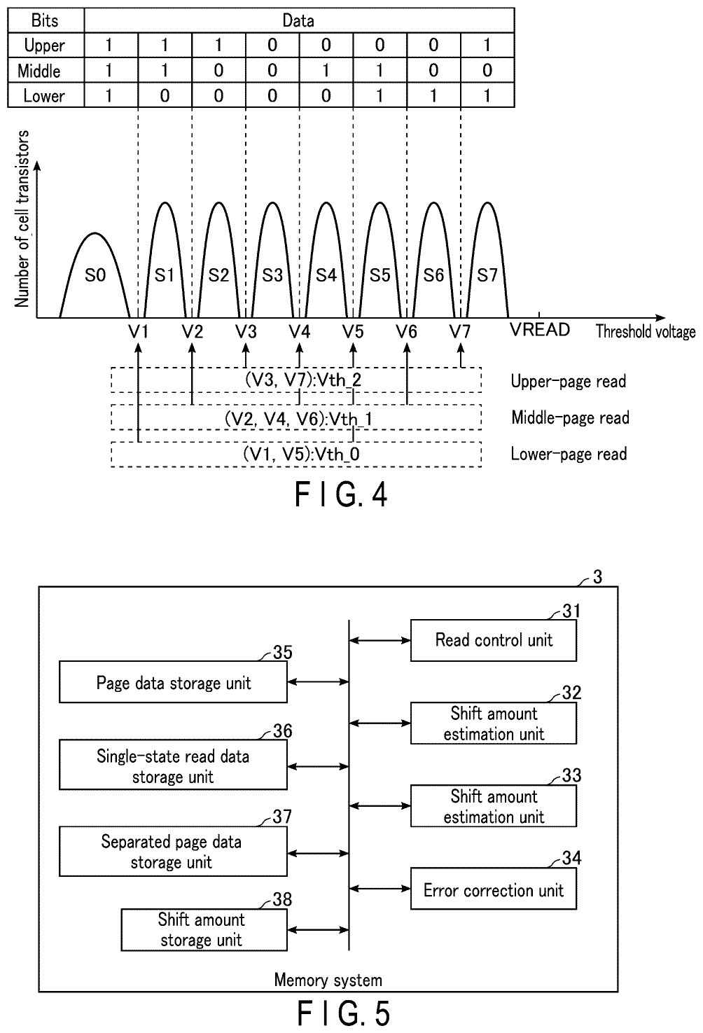

The nonvolatile memory 20 can store two or more bits of data in a single cell transistor MT. FIG. 4 illustrates an example of distribution of threshold voltages of the cell transistors of the memory system 3 of the first embodiment each storing 3-bit data and the mapping of the data. The threshold voltage of each cell transistor MT has a magnitude corresponding to the stored data based on the amount of electrons in the charge storage layer IA. In the case of 3-bit storage, each cell transistor MT is in one of “S0”, “S1”, “S2”, “S3”, “S4”, “S5”, “S6”, and “S7” states based on the threshold voltage. The cell transistors MT in the “S0”, “S1”, “S2”, “S3”, “S4”, “S5”, “S6”, and “S7” states have higher threshold voltages in the named order. The cell transistor MT is brought to the “S0” state when the threshold voltage of the cell transistor MT is lowered through the data erase.

Through the data write, a write target cell transistor MT is maintained in the “S0” state or brought to one of the “S1”, “S2”, “S3”, “S4”, “S5”, “S6”, and “S7” states based on the data to be written. Even a plurality of cell transistors MT that store the same 3-bit data may have different threshold voltages. A set of threshold voltages in a single state is referred to as a threshold voltage lobe.

3-bit data can be assigned to any state. In one example, each state is treated as having the following 3-bit data. Regarding “ABC” in the following description, A, B, and C indicate values of upper, middle, and lower bits, respectively.
The “S0” state: “111”
The “S1” state: “110”
The “S2” state: “100”
The “S3” state: “000”
The “S4” state: “010”
The “S5” state: “011”
The “S6” state: “001”
The “S7” state: “101”

The data read is based on determination of the state of a read target cell transistor MT. Read voltages VCGR having different magnitudes are used for the determination of the state. While the cell transistor MT is receiving the read voltage VCGR at its gate electrode, the cell transistor remains off if the cell transistor MT has a threshold voltage equal to or higher than the read voltage VCGR, and remains on if the cell transistor MT has a threshold voltage lower than the read voltage VCGR. Based on this, it is determined whether the read target cell transistor MT has a threshold voltage higher than the read voltage VCGR.

Determination whether the read target cell transistor MT is in a state higher than the “S0”, “S1”, “S2”, “S3”, “S4”, “S5”, and “S6 states is performed using read voltages V1, V2, V3, V4, V5, V6, and V7, respectively. The read voltages V1, V2, V3, V4, V5, V6, and V7 are higher in the named order. Obtaining a set of bits indicating whether the cell transistors MT are on or off by application of the read voltages V1, V2, V3, V4, V5, V6, and V7, or data read, may be referred to as 1R, 2R, 3R, 4R, 5R, 6R, and 7R, respectively.

A set of data of bits (or, bit string) at the same position (or, digit) in the cell transistors MT of a single cell unit CU corresponds to a single page. A set of data of the least significant (i.e., first digit from the bottom) bits (or, bit string), or lower bits, of the cell transistors MT of each cell unit CU is referred to as a lower page. A set of data of the second least significant bits (or, bit string), or middle bits, of the cell transistors MT of each cell unit CU is referred to as a middle page. A set of data of the third least significant bits, or upper bits, of the cell transistors MT of each cell unit CU is referred to as an upper page.

Read of data of the lower page uses the read voltages V1 and V5. The set of read voltages V1 and V5, which are used in the lower-page read, may be referred to as a read voltage group Vth_0.

Read of data of the middle page uses the read voltages V2, V4 and V6. The set of read voltages V2, V4, and V6, which are used in the middle page read, may be referred to as a read voltage group Vth_1.

Read of data of the upper page uses the read voltages V3 and V7. The set of read voltages V3 and V7, which are used in the upper page read, may be referred to as a read voltage group Vth_2.

The memory controller 10 specifies the read voltages V1 to V7, to be used in a data read, using digital-to-analogue converter (DAC) values respectively representing shift amounts ΔV1 to ΔV7 from a default value. A set of shift amounts ΔV1 and ΔV5 to be respectively added to the read voltages V1 and V5 of the read voltage group Vth_0 may be referred to as a “shift amount group ΔVth0”. A set of shift amounts ΔV2, ΔV4 and ΔV6 to be respectively added to the read voltages V2, V4 and V6 of the read voltage group Vth_1 may be referred to as a “shift amount group ΔVth1”. A set of shift amounts ΔV3 and ΔV7 to be respectively added to the read voltages V3 and V7 of the read voltage group Vth_2 may be referred to as a “shift amount group ΔVth2”.

Data to be written into a page may be randomized by the memory controller 10 so as to suppress a bias in distribution of the bits of “1” data and the bits of “0” data. As a result of the randomization, it can be expected that, in a cell unit CU into which data has been written, the number of transistors to which cell transistors MT in each state belong is nearly uniform.

### 1.2. Operation

FIG. 5 illustrates an example of functional blocks during operation of the memory system according to the first embodiment. As illustrated in FIG. 5, the memory system 3 includes, during operation of the memory system 3, functional blocks such as a read control unit 31, a shift amount estimation unit 32, a shift amount estimation unit 33, an error correction unit 34, a page data storage unit 35, a single-state read data storage unit 36, a separated page data storage unit 37, and a shift amount storage unit 38. Some of the functions may be performed by one or more functional blocks other than those mentioned above, and the functional blocks may be divided into smaller functional sub-blocks.

Each of the read control unit 31, the shift amount estimation unit 32, the shift amount estimation unit 33, the page data storage unit 35, the single-state read data storage unit 36, the separated page data storage unit 37, and the shift amount storage unit 38 is realized by some of the resources of one or more of the CPU 11, the ROM 12, the RAM 13, the nonvolatile memory interface 15, the volatile memory interface 16, and the volatile memory 30.

The error correction unit 34 is, in an example, the decoder 172 itself.

The read control unit 31 controls reads of all types of data from the nonvolatile memory 20. To execute a read request from the host device 2, the read control unit 31 specifies data read from the nonvolatile memory 20, controls a read of data, generates an instruction to read the data, and transmits the generated instruction to the nonvolatile memory 20.

The shift amount estimation unit 32 controls a first-type shift amount estimation, to be described later. The first-type shift amount estimation refers to an estimation of a shift amount (or, an adjustment amount) of a read voltage expected to lead to a read of page data including a lower number of errors (or, fail bits). Hereinafter, “*** data” (where *** is a given character string) may be simply referred to as “data”.

The shift amount estimation unit 33 controls a second-type shift amount estimation, to be described later. The second-type shift amount estimation refers to an estimation of a shift amount of a read voltage expected to lead to a read of page data including a lower number of errors. The second-type shift amount estimation differs from the first-type shift amount estimation. The second-type shift amount estimation is an estimation that can be performed if data containing an error in a page (or, pre-error-correction data) and data in which an error has been corrected (or error-corrected data) are available.

The page data storage unit 35 stores data (or, page data) read from a page of the nonvolatile memory 20.

The single-state read data storage unit 36 stores data obtained by a single-state read of a cell unit CU by the nonvolatile memory 20. The single-state read refers to acquisition of a set of bits with a value that indicates either ON or OFF of cell transistors MT resulting from application of a single read voltage to a single cell unit CU, unlike a read of page data (i.e., a page read).

The separated page data storage unit 37 stores separated page data. The separated page data is data generated from page data using single-state read data, and includes only bits that satisfy certain conditions of the page data.

The shift amount storage unit 38 stores a shift amount.

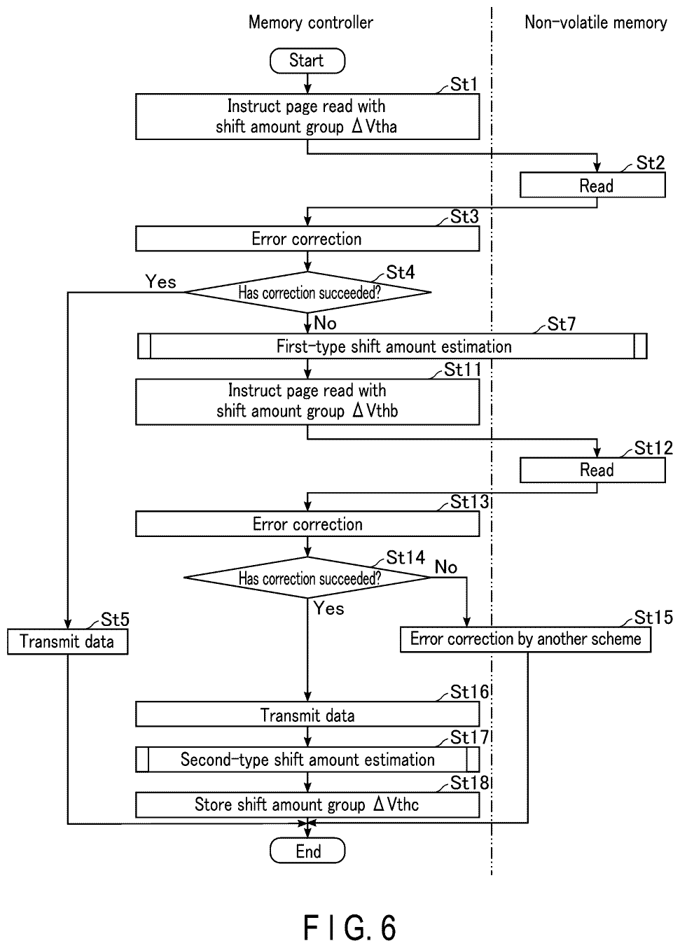

FIG. 6 illustrates a flow of an operation of the memory system according to the first embodiment. The flow of FIG. 6 is started if the memory controller 10 receives a data read request from the host device 2, and specifies a page from which data is to be read to execute the data read request. A read target page may be referred to as a “selected page”. A cell unit CU that provides the selected page may be hereinafter referred to as a select cell unit “CUw”.

As illustrated in FIG. 6, the memory controller 10 gives a data read instruction to the nonvolatile memory 20 to read data from the selected page using a shift amount group ΔVtha (St1). The data read instruction contains information to instruct a page read, address information to specify a data read target page, and a shift amount group ΔVtha. There may be a case where the shift amount group ΔVtha is zero, namely, where a default read voltage group Vth is used.

Upon receiving the instruction, the nonvolatile memory 20 reads data Da from the selected page using the shift amount group ΔVtha (St2). The nonvolatile memory 20 transmits the read data Da to the memory controller 10.

Upon receiving the data Da, the memory controller 10 attempts to correct an error in the data Da using the error correction unit 34 (St3).

If the error correction succeeds (St4; Yes), the memory controller 10 transmits data based on the data Da to the host device 2 as the read request target (St5). Thereby, the flow ends. The case where the error correction succeeds includes a case where an error is not detected.

If the error correction fails (St4; No), the memory controller 10 performs a first-type shift amount estimation (St7). The first-type shift amount estimation includes multiple page reads of the selected page using different shift amount groups ΔVth, and arithmetic operations by the memory controller 10. Further details of the first-type shift amount estimation will be given later. Through the first-type shift amount estimation, a shift amount group ΔVthb expected to lead to a read of page data including a lower number of errors is obtained in the memory controller 10.

The memory controller 10 instructs the nonvolatile memory 20 to read data from the selected page using the shift amount group ΔVthb (St11).

Upon receiving the instruction, the nonvolatile memory 20 reads data Db from the selected page using the shift amount group ΔVthb (St12). The nonvolatile memory 20 transmits the read data Db to the memory controller 10.

Upon receiving the data Db, the memory controller 10 attempts to correct an error in the data Db using the error correction unit 34 (St13).

If the error correction fails (St14; No), the memory controller 10 attempts to correct the error in the selected page using another scheme (St15). Examples of the different scheme include use of a more advanced level of error correction method. After step St15 ends, the flow of FIG. 6 ends.

If the error correction succeeds (St14; Yes), the memory controller 10 transmits data based on the data Dc to the host device 2 as the read request target data (St16). The data Dc is error-corrected data of the data Db.

The memory controller 10 performs a second-type shift amount estimation (St17). In the processing at step St17, the pre-error-correction data Db and the error-corrected data Dc are used. Further details of the second-type shift amount estimation will be given later. Through the second-type shift amount estimation, a shift amount group ΔVthc expected to lead to a read of data including a lower number of errors is obtained in the memory controller 10.

The memory controller 10 stores the shift amount group ΔVthc for the selected page in the shift amount storage unit 38 as a latest value (St18). Thereby, the flow of FIG. 6 ends. The shift amount group ΔVthc is used in the next data read from the selected page, and is used as, in an example, the shift amount group ΔVtha.

### 1. 2. 1. First-Type Shift Amount Estimation

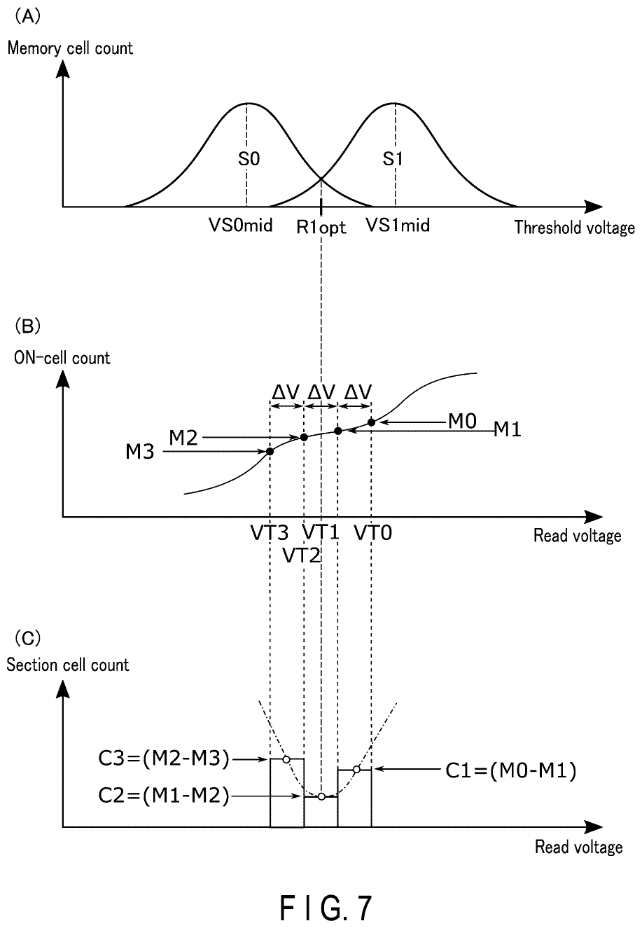

FIG. 7 illustrates a concept of the first-type shift amount estimation by the memory system according to the first embodiment. FIG. 7 illustrates in part (A), as an example, threshold voltage lobes of the “S0” state and the “S1” state. With a change in threshold voltage immediately after data writing, the two threshold voltage lobes are integrated in a partially overlapping manner, and form a local minimum value. FIG. 7 illustrates in part (B) a relationship between the read voltage and the number M of cell transistors MT that are ON in accordance with the read voltage, or ON-cell count M. FIG. 7 illustrates in part (C) differences in ON-cell counts between two different read voltages.

As illustrated in part (B), as the read voltage V is lowered, the ON-cell count M rapidly decreases at a voltage slightly lower than a voltage VS1mid, and |dM/dV| reaches a local maximum. As the read voltage V is further lowered, a rate of decrease of the ON-cell count M becomes smaller and reaches a local minimum at a read voltage V with a certain value. The local minimum value of the rate of decrease of the ON-cell count M becomes zero if the threshold voltage lobes of the “S0” and “S1” states do not overlap; however, since the two threshold voltage lobes overlap, the local minimum value of the rate of decrease of the ON-cell count M is a positive value that is not zero. As the read voltage V is further lowered, the rate of decrease of the ON-cell count M becomes larger again, and |dM/dV| reaches a local maximum again at a voltage slightly higher than a voltage VS0mid.

Through such an estimation of a local minimum point of the threshold voltage based on a change in the ON-cell count M, a read voltage at the local minimum point can be used. Specifically, a single-state read is performed using the voltage VT0 as a read voltage. As a result of this, the ON-cell count is M0. Subsequently, a single-state read is performed using the voltage VT1 lower than the voltage VT0 by ΔV as the read voltage. As a result of this, the ON-cell count is M1. Thus, the number of cell transistors MT that turn off during the drop of the read voltage from the voltage VT0 to the voltage VT1 is C1=M0−M1, as illustrated in part (C). That is, the number of cells with a threshold voltage between the voltage VT0 and the voltage VT1 is C1.

Thereafter, a single-state read is performed using the voltage VT2 lower than the voltage VT1 by ΔV as the read voltage. As a result of this, the ON-cell count is M2. Thus, the number of cell transistors MT that turn off during the drop of the read voltage from the voltage VT1 to the voltage VT2 is C2=M1−M2. That is, the number of cells with a threshold voltage between the voltage VT2 and the voltage VT1 is C2. The cell count C1 is greater than the cell count C2. Thus, the voltage at which |dM/dV| becomes the minimum is considered to be at least lower than the voltage VT1.

Thereafter, a single-state read is performed using the voltage VT3 lower than the voltage VT2 by ΔV as the read voltage. As a result of this, the ON-cell count is M3. Thus, the number of cell transistors MT that turn off during the drop of the read voltage from the voltage VT2 to the voltage VT3 is C3=M2−M3. That is, the number of cells with a threshold voltage between the voltage VT3 and the voltage VT2 is C3. The cell count C3 is greater than the cell count C2.

As a result of the foregoing, the threshold voltage distribution as illustrated by the dash-dotted line in part (C) can be estimated by an section cell count C. Thus, the threshold voltage distribution is estimated to have a local minimum point between the voltage VT1 and the voltage VT2, which is a section in which the section cell count C reaches a local minimum. The estimated local minimum point is a point at which an overlap between the threshold voltage lobes of the “S0” and “S1” states is estimated to be the smallest. Use of the voltage at the local minimum point as the read voltage V1 may lead to a decrease in the number of fail bits in the read data. A difference between the voltage at the local minimum point and a default read voltage is the estimated shift amount.

As described above with reference to FIG. 4, the values in page data may be distributed over non-adjacent states. That is, “1” data in lower-page data is associated with a range of voltages equal to or lower than the read voltage V1 and a range of voltages equal to or higher than the read voltage V5. Thus, it may be difficult to correctly calculate the ON-cell count using only a plurality of items of lower-page data obtained by performing multiple lower-page reads while shifting a read voltage.

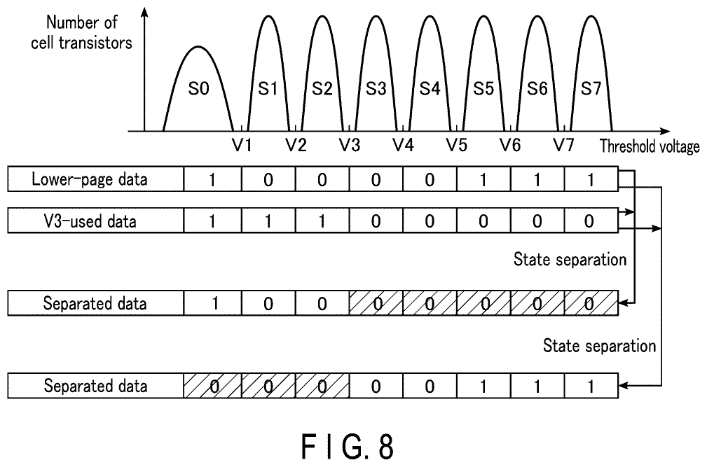

Accordingly, state separation is performed, as illustrated in FIG. 8. FIG. 8 illustrates data obtained by an operation by the memory system according to the first embodiment.

For state separation, the memory controller 10 causes the nonvolatile memory 20 to perform at least one single-state read. In a single-state read for state separation, a read voltage located between multiple discontinuous voltage ranges to which the same value is assigned is used, and such a read voltage is based on a read target page. In an example, the read voltage V3 is used in a single-state read for a lower-page read. Data obtained by a single-state read may be referred to as “separation data”. Lower-page data is masked by the separation data. The masking can be performed by an appropriate logical operation of the lower-page data and the separation data. Through the masking of the lower-page data, the masked bits have “0” data, irrespective of their values prior to the masking. The unmasked bits have data containing information, which may be referred to as a “valid data portion”.

Specifically, data is obtained in which the bits of cell transistors MT with a threshold voltage less than the read voltage V1 have “1” data, and the bits of cell transistors MT with a threshold voltage equal to or higher than the read voltage V1 have “0” data. The masked bits are hatched. Similarly, through an appropriate logical operation of the lower-page data and the separation data, data is obtained in which the bits of cell transistors MT with a threshold voltage less than the read voltage V5 have “0” data, and the bits of cell transistors MT with a threshold voltage equal to or higher than the read voltage V5 have “1” data.

A state separation of middle-page data may be similarly performed using data obtained by a single-state read with the read voltage V3 and data obtained by a single-state read with the read voltage V5. A state separation of upper-page data may be performed using data obtained by a single-state read using the read voltage V5.

Through such state separation, the ON-cell count can be correctly calculated.

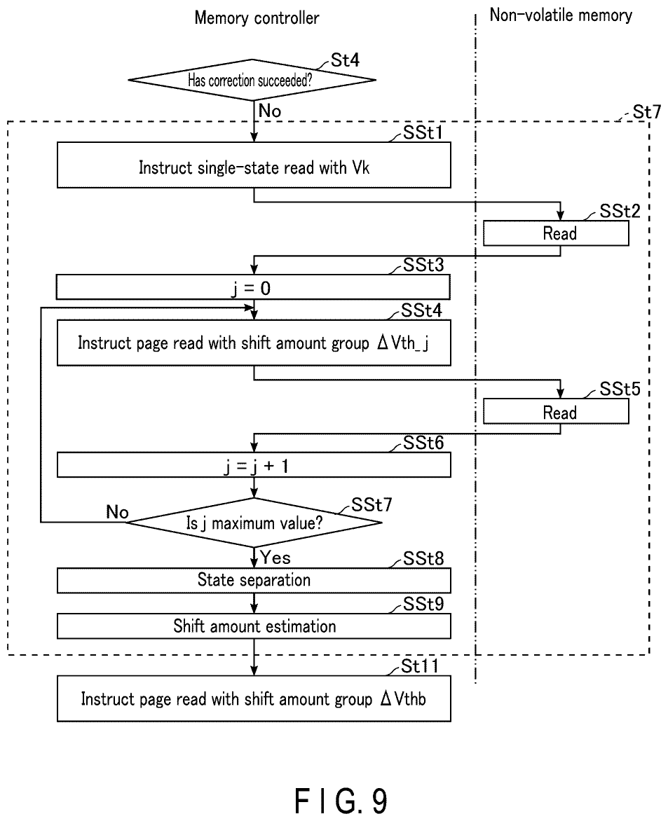

FIG. 9 illustrates a flow of an operation of the memory system according to the first embodiment. FIG. 9 illustrates a sub-flow of step St7 (the first-type shift amount estimation) in the flow of FIG. 6, which is an operation by the memory controller 10, in particular, the shift amount estimation unit 32.

As illustrated in FIG. 9, the memory controller 10 instructs the nonvolatile memory 20 to perform a single-state read of a selected cell unit CUw using a read voltage Vk (SSt1). Here, k takes a value based on separation data to be acquired for state separation. If a shift amount is added to the read voltage Vk, the shift amount may be included in the instruction.

Upon receiving the instruction, the nonvolatile memory 20 performs a single-state read of the selected cell unit CUw using the read voltage Vk (SSt2). The nonvolatile memory 20 transmits the obtained single-state read data DkR to the memory controller 10. The memory controller 10 stores the read data DkR in the single-state read data storage unit 36.

The set of steps SSt1 and SSt2 is performed the number of times corresponding to the selected page, namely, the number of items of separation data necessary for state separation, and the number of items of data DKR corresponding to the number of items of separation data necessary for state separation are acquired.

The memory controller 10 sets 0 to a variable j (SSt3).

The memory controller 10 instructs the nonvolatile memory 20 to read data from the selected page using the shift amount group ΔVth_j (SSt4). The shift amount group ΔVth_j differs from the shift amount group ΔVtha, and also differs from the shift amount group ΔVth_j that was previously used during the flow of FIG. 9. If, as a specific example, the shift amount group ΔVtha includes a voltage corresponding to the voltage VT0 in FIG. 7, the shift amount group ΔVth_j includes the voltage VT1. Specifically, if the selected page is a lower page, the shift amount group ΔVth_j includes shift amounts ΔV1_j and ΔV5 j. If the selected page is a middle page, the shift amount group ΔVth_j includes shift amounts ΔV2_j, ΔV4_j, and ΔV6_j. If the selected page is an upper page, the shift amount group ΔVth j includes shift amounts ΔV3_j and ΔV7_j.

Upon receiving an instruction, the nonvolatile memory 20 reads data D_j from the selected page using the shift amount group ΔVth_j (SSt5). The nonvolatile memory 20 transmits the obtained page data D_j to the memory controller 10. The data D_j contains information about the ON-cell count illustrated in FIG. 7; that is, the ON-cell count can be known from the data D_j. The data D_j is kept stored in the page data storage unit 35 until at least completion of a state separation process at step SSt8, to be described below.

The memory controller 10 increments j by 1 (SSt6). If the values of j can be distinguished from one another, j may be referred to as one of “j1”, “j2”, “j3”, . . .

If j is not a predetermined maximum value (SSt7; Yes), the flow advances to step SSt4. The maximum value defines the number of ON cells used in the first-type shift amount estimation, and is based on details of the method of the first-type shift amount estimation. The description to be given below and the drawings to be referred to below are based on an example in which the maximum value of j is 5.

If j is the maximum value (SSt7; Yes), the memory controller 10 performs state separation of the data D_j, with respect to each of the cases where j takes one of 0 to 4 (SSt8). Thereby, separated page data DSp_j is generated from the data D_j, with respect to each of the cases where j takes one of 0 to 4 and with respect to each of the cases where p takes all possible values based on the selected page. Here, p takes either 0 or a positive integer, depending on the selected page. That is, if the selected page is a lower page, p is either 1 or 5. If the selected page is a middle page, p is one of 2, 4, or 6. If the selected page is an upper page, p is either 3 or 7. If the values of p can be distinguished from one another, p may be referred to as one of “p1”, “p2”, “p3”, . . . . The separated page data DSp_j is stored in the separated page data storage unit 37.

The memory controller 10 estimates the shift amount group ΔVthb using the data DSp_j (SSt9).

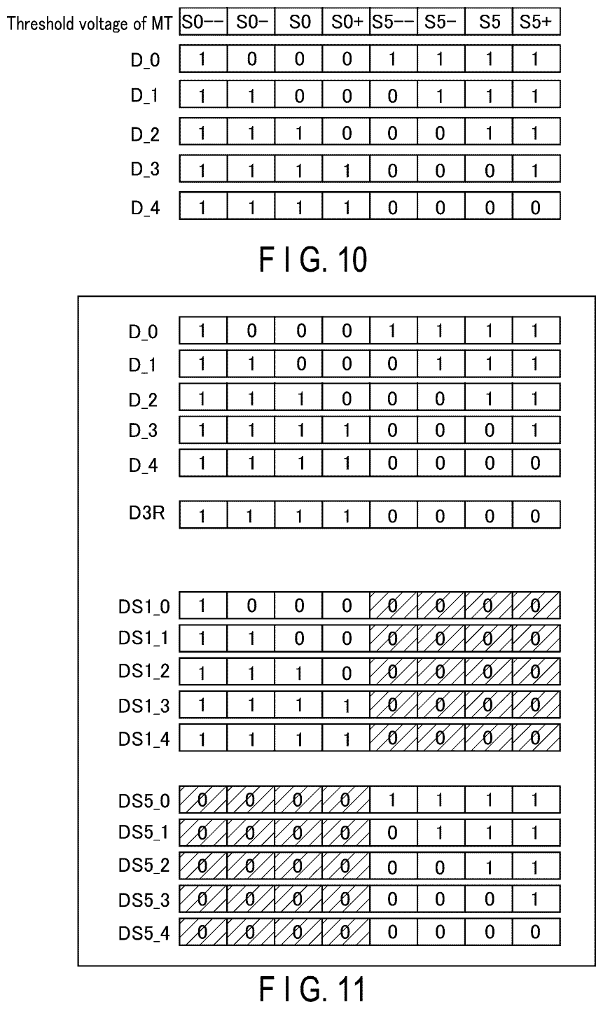

FIG. 10 illustrates an example of data obtained during an operation of the memory system according to the first embodiment. FIG. 10 illustrates, an example of data obtained in the course of a loop of steps SSt4, SSt5, SSt6, and SSt7 of the flow of FIG. 9 by taking lower pages as a representative.

The shift amount group ΔVth_j used in step SSt4 differs according to j. Thus, cell transistors MT that are ON based on the threshold voltage of the cell transistors MT of a data read target cell unit CU differ according to j, which in turn means that the page data D_j differs according to j, as illustrated in FIG. 10. Specifically, “1”, “0”, “0”, “0”, “1”, “1”, “1”, and “1” are read as page data D_0 from cell transistors MT having threshold voltages S1−−, S1−, S1, S1+, S5−−, S5−, S5, and S5+, respectively. The threshold voltages Sk−−, Sk−, Sk, and Sk+ are higher in this order in the threshold voltage lobe of the “Sk” state. Depending on j, the larger the shift amounts ΔV1 and ΔV5 used, the more cell transistors MT with higher threshold voltages turn on. As a result, distributions of the “0” data and the “1” data in the data D_j differ depending on j. For example, “1”, “1”, “0”, “0”, “0”, “1”, “1”, and “1” are read as data D_1 from the cell transistors MT with threshold voltages S1−−, S1−, S1, S1+, S5−−, S5−, S5, and S5+, respectively.

FIG. 11 illustrates another example of data obtained during an operation by the memory system according to the first embodiment. FIG. 11 illustrates an example of data obtained at step SSt8 of the flow of FIG. 9, by taking lower pages as a representative. As illustrated in FIG. 11, separated page data DS1_j and DS5_j are generated from the page data D_j, with respect to each of the cases where j takes one of 0 to 4. The data DS1_j and DS5_j may be abandoned after completion of the estimation of the shift amount group ΔVthb at step SSt9, namely, may be treated as invalid data.

### 1. 2. 2. Second-Type Shift Amount Estimation

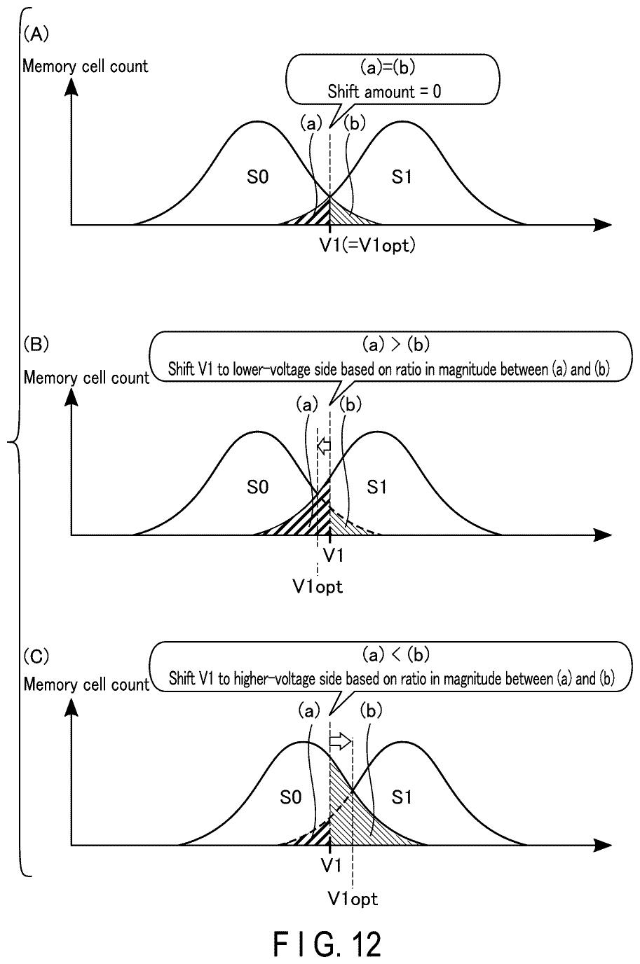

FIG. 12 illustrates a concept of a second-type shift amount estimation by the memory system according to the first embodiment. FIG. 12 illustrates estimation of a shift amount ΔV1 of the read voltage V1 as a representative.

In FIG. 12, the number of cell transistors MT that had been shifted to the “S1” state but have been determined to be in the “S0” state, namely, the memory cell count E_01, corresponds to the area of the region (a) in FIG. 12. The number of cell transistors MT that had been shifted to the “S0” state but have been determined to be in the “S1” state, namely, the memory cell count E_10, corresponds to the area of the region (b). The memory cell counts E_01 and E_10 are obtained by comparison between data prior to the error correction (e.g., data input to the error correction unit 34) and error-corrected data of the same data.

FIG. 12 illustrates in part (A) a case where the used read voltage V1 is equal to a threshold voltage V1opt at the position where the threshold voltage lobes of the “S0” and “S1” states intersect each other. In the case illustrated in part (A), the region (a) and the region (b) are equal in area. In this case, the fail bit count E (=E_01+E_01) in data read from cell transistors MT that are in either the “S0” or “S1” state is expected to be the minimum.

FIG. 12 illustrates in part (B) a case where the used read voltage V1 is higher than the threshold voltage V1opt. In this case, the region (a) has a greater area than the region (b). Also, in this case, the fail bit count E is greater than the fail bit count E in the case of part (A). In the case of part (B), if the read voltage V1 shifted to the lower-voltage side is used during the next data read from the selected page, the fail bit count E is expected to be smaller.

FIG. 12 illustrates in part (C) a case where the used read voltage V1 is lower than the threshold voltage V1opt. In this case, the region (a) has a smaller area than the region (b). Also, in this case, the fail bit count E is greater than the fail bit count E in the case of part (A). In the case of part (C), if the read voltage V1 shifted to the higher-voltage side is used during the next data read from the selected page, the fail bit count E is expected to be smaller.

An absolute value of a difference in area between the regions (a) and (b) becomes greater the further the read voltage V1 deviates from the threshold voltage V1opt. Thus, in the cases of parts (B) and (C), the memory controller 10 determines the shift amount ΔV1 for the read voltage V1 based on a ratio between the area of the region (a) and the area of the region (b). The further the ratio is deviated from 1, the greater the shift amount to be used. The memory controller 10 determines, based on an absolute value of the difference in area between the regions (a) and (b), a relationship with the shift amount ΔV1 for making the read voltage V1 close to the threshold voltage V1opt by referring to a shift amount correspondence table. The shift amount correspondence table shows various relationships between the absolute value of the difference in area between the regions (a) and (b) and the shift amount ΔV1 for making the read voltage V1 closer to the threshold voltage V1opt. The shift amount correspondence table is prepared in advance, and is stored in the shift amount storage unit 38.

For the other read voltages V2 to V7, shift amounts ΔV2 to ΔV7 are similarly estimated as in the case of the read voltage V1.

A set of shift amounts ΔV1 and ΔV5 obtained by the estimation is the shift amount group ΔVth0. A set of shift amounts ΔV2, ΔV4 and ΔV6 obtained by the estimation is the shift amount group ΔVth1. A set of shift amounts ΔV3 and ΔV7 obtained by the estimation is the shift amount group ΔVth2.

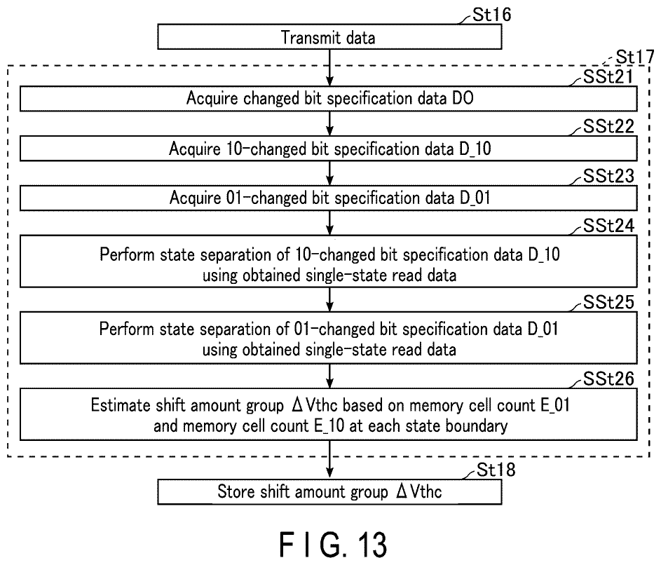

FIG. 13 illustrates a flow of an operation of the memory system according to the first embodiment. FIG. 13 illustrates a sub-flow of step St17 (or, the second-type shift amount estimation) in the flow of FIG. 6, which is an operation performed by the memory controller 10, in particular, the shift amount estimation unit 33.

As illustrated in FIG. 13, the memory controller 10 acquires changed bit specification data DO (SSt21). The data DO is data having a specific value (e.g., “1”) in error-corrected bits in the error-corrected data Dc. The data DO can be generated by any method. In an example, the data DO is generated by an exclusive OR (XOR) operation of the pre-error correction data Db and the error-corrected data Dc.

The memory controller 10 acquires 10-changed bit specification data D_10 (SSt22). In the data D_10, a 10-changed bit has a specific value (e.g., “1”) in the error-corrected data Dc. The 10-changed bit is a bit indicating a cell transistor MT into which data had been written as storing “1” data but which has been determined to be storing “1” data. The data D_10 can be generated by any method. In an example, the data D_10 is generated by a logical conjunction of the data DO and the data Dc.

A change from the “1” data to the “0” data may occur at a boundary between discrete states. Specifically, in the case of a lower-page read, such a change occurs in the bits of cell transistors MT that had been brought to the “S0” state but have been determined to be in the “S1” state, and in the bits of cell transistors MT that had been brought to the “S5” state but have been determined to be in the “S4” state. Accordingly, the data D_10 has a specific value indicating a change in both of the cases where the change occurs at a boundary between the “S0” and “S1” states and at a boundary between the “S4” and “S5” states. It is unknown in which of the state boundaries such a change occurs. The same applies to the other pages.

The memory controller 10 acquires 01-changed bit specification data D_01 (SSt23). In the data D_01, a 01-changed bit has a specific value (e.g., “1”) in the error-corrected data Dc. The 01-changed bit is a bit indicating a cell transistor MT into which data had been written as storing “0” data but which has been determined to be storing “1” data. The data D_01 can be generated by any method. In an example, the data D_01 is generated by a logical conjunction of the data DO and negation of the data Dc.

A change from the “0” data to the “1” data may occur at a boundary between discrete states. Specifically, in the case of a lower-page read, such a change occurs in the bits of cell transistors MT that had been brought to the “S1” state but have been determined to be in the “S0” state, and in the bits of cell transistors MT that had been brought to the “S4” state but have been determined to be in the “S5” state. Accordingly, the data D_01 has a specific value indicating a change in both of the cases where the change occurs at a boundary between the “S0” and “S1” states and at a boundary between the “S4” and “S5” states. It is unknown in which of the state boundaries such a change is occurring. The same applies to the other pages.

Step SSt23 may be performed prior to step SSt22.

The memory controller 10 performs state separation of the 10-changed bit specification data D_10 using single-state read data DkR obtained at step SSt1 in FIG. 9 (SSt24). Based on the same principle as that described above with reference to FIG. 8, the same number of items of separated 10-changed bit specification data D_10_Sp as the number of items of values of p are generated from the data D_10 by state separation. The data D_10_Sp contains information specifying 10-changed bits that have occurred only at a boundary between the “Sp” state and the “Sp-1” state. In the case of a lower page, data D_10_S1 and data D_10_S5 are generated.

The memory controller 10 performs state separation of the 01-changed bit specification data D_01 using single-state read data DkR obtained at step SSt1 in FIG. 9 (SSt25). The same number of items of separated 01-changed bit specification data D_01_Sp as the number of items of values of p are generated from the data D_01 by state separation. The data D_01_Sp contains information specifying 01-changed bits that have occurred only at a boundary between the “Sp” state and the “Sp-1” state. In the case of a lower page, data D_01_S1 and data D_01_S5 are generated.

Step SSt25 may be performed prior to step SSt24.

The memory controller 10 estimates the shift amount group ΔVthc using the data D_10_Sp and the data D_01_Sp (SSt26). A memory cell count E_10_Sp at the boundary between the “Sp” state and the “Sp-1” state is obtained by calculation from the data D_10_Sp. The memory cell count E_10_Sp is a memory cell count E_10 at the boundary between the “Sp” state and the “Sp-1” state. A memory cell count E_01_Sp at the boundary between the “Sp” state and the “Sp-1” state is obtained by calculation from the data D_01_Sp. The memory cell count E_01_Sp is a memory cell count E_01 at the boundary between the “Sp” state and the “Sp-1” state. In the case of a lower page, memory cell counts E_10_S1, E_10_S5, E_01_S1, and E_01_S5 are obtained. The shift amount group ΔVthc is estimated from the obtained memory cell counts E_10_S1, E_10_S5, E_01_S1, and E_01_S5 by the method described above with reference to FIG. 12.

### 1.3. Advantages (Advantageous Effects)

According to the first embodiment, it is possible to provide a memory system that reads data with high efficiency, as described below.

With the first-type shift amount estimation, it is difficult to realize high precision due to reasons such as noise mixed into data during the processing and a difference between the threshold voltage distribution immediately after data writing to cell transistors and the threshold voltage distribution during the first-type shift amount estimation after passage of a predetermined period of time.

The second-type shift amount estimation is, in general, autonomously and periodically performed by a memory system while the memory system is not performing a process in response to a request from a host device. The second-type shift amount estimation realizes high precision but requires data that does not contain an error for execution. In the case where the memory cell stores data of 2 bits or more, as in the first embodiment, separation data is also required.

According to the first embodiment, the second-type shift amount estimation is performed as part of a read of page data. If error correction of the page data read using the result of the first-type shift amount estimation succeeds, second-type shift amount estimation is subsequently performed. Since error-corrected page data has been obtained by the first-type shift amount estimation, it is possible to subsequently perform second-type shift amount estimation. By using the shift amount obtained by the second-type shift amount estimation in the next page read, it is possible to suppress an error in the next page read, thus improving precision in the data read. In addition, by maintaining the separation data obtained in the first-type shift amount estimation until the second-type shift amount estimation and using the separation in the second-type shift amount estimation, it is possible to perform the second-type shift amount estimation with high efficiency.

### 2. Second Embodiment

A second embodiment is based on the first embodiment, and differs from the first embodiment in the method of the second-type shift amount estimation. The hardware configuration the and functional block configuration of a memory system 3 according to the second embodiment are the same as those of the first embodiment.

### 2. 1. Operation

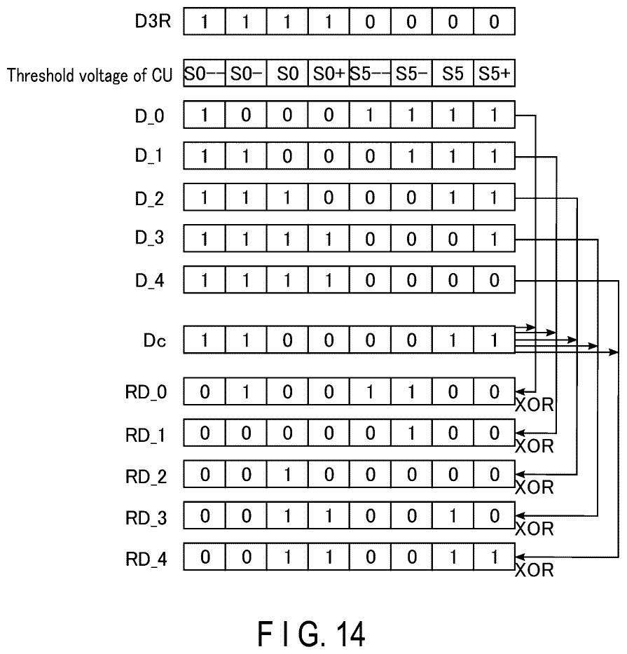

Each of FIGS. 14 to 19 illustrates a concept of a second-type shift amount estimation by the memory system 3 according to the second embodiment. FIGS. 14 to 19 illustrate estimation of shift amounts ΔV1 and ΔV5 of lower pages as a representative.

The memory controller 10 keeps storing the separation data (i.e., single-state read data DkR (D3R)) obtained at steps SSt1 and SSt2 in the page data storage unit 35 until completion of the separation data used at step St17 (second-type shift amount estimation).

The memory controller 10 keeps storing the page data D_j obtained in a loop of steps SSt4, SSt5, SSt6, and SSt7 in the page data storage unit 35 until completion of the page data D_j used at step St17, with respect to each of the cases where j takes one of 0 to 4. The error-corrected data Dc is stored in the error correction unit 34.

As illustrated in FIG. 14, reference data RD_j is generated by an exclusive OR (XOR) operation of the error-corrected data Dc and the page data D_j with respect to each of the cases where j takes one of 0 to 4.

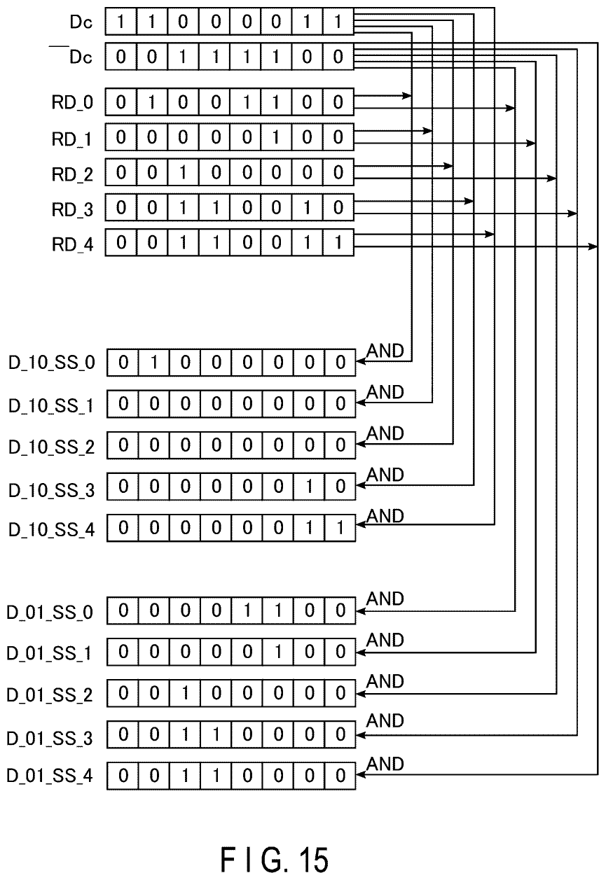

As illustrated in FIG. 15, 10-changed bit specification data D_10_SS_j is generated by an AND operation of the error-corrected data Dc and reference data RD j with respect to each of the cases where j takes one of 0 to 4. The data D_10_SS_j contains information specifying 10-changed bits in the data D_j.

01-changed bit specification data D_01_SS j is generated by an AND operation of negation of the error-corrected data Dc and the reference data RD_j with respect to each of the cases where j is one of 0 to 4. The data D_01_SS_j contains information specifying 01-changed bits in the data D_j.

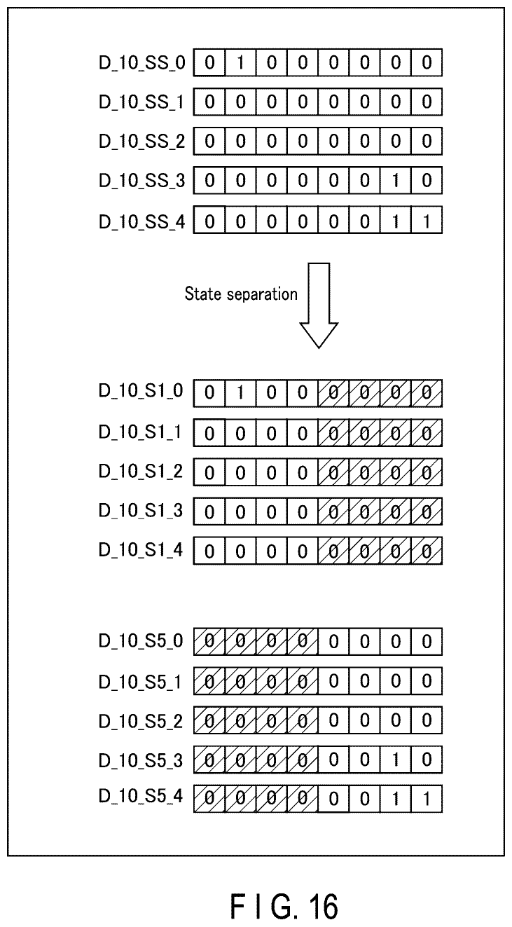

As illustrated in FIG. 16, state separation of the data D_10_SS_j is performed using data D3R with respect to each of the cases where j is one of 0 to 4. As a result, separated 10-changed bit specification data D_10_S1_j and D_10_S5_j are generated from the data D_10_SS_j with respect to each of the cases where j takes one of 0 to 4.

The data D_10_S1_j contains information specifying bits of cell transistors MT that had been brought to the “S0” state but have been determined to be in the “S1” state. The data D_10_S1_j is data in which bits of cell transistors MT that had been brought to the “S5” state but have been determined to be in the “S4” state are masked, and does not contain information specifying the bits of the cell transistors MT that had been brought to the “S5” state but have been determined to be in the “S4” state.

The data D_10_S5_j contains information specifying bits of cell transistors MT that had been brought to the “S5” state but have been determined to be in the “S4” state. The data D_10_S5_j is data in which bits of cell transistors MT that had been brought to the “S0” state but have been determined to be in the “S1” state are masked, and does not contain information specifying the bits of the cell transistors MT that had been brought to the “S0” state but have been determined to be in the “S1” state.

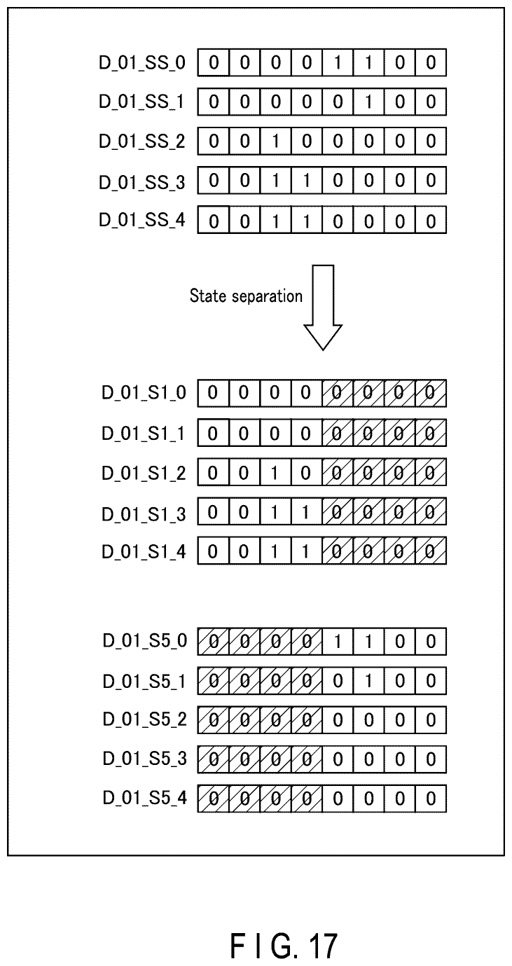

As illustrated in FIG. 17, state separation of the data D_01_SS_j is performed using data D3R with respect to each of the cases where j takes one of 0 to 4. As a result, separated 01-changed bit specification data D_01_S1_j and D_01_S5_j are generated from the data D_01_SS_j with respect to each of the cases where j takes one of 0 to 4.

The data D_01_S1_j contains information specifying bits of cell transistors MT that had been brought to the “S1” state but have been determined to be in the “S0” state. The data D_01_S1_j is data in which bits of cell transistors MT that had been shifted to the “S4” state but have been determined to be in the “S5” state are masked and does not contain information specifying the bits of the cell transistors MT that had been brought to the “S4” state but have been determined to be in the “S5” state.

The data D_01_S5_j contains information specifying bits of cell transistors MT that had been brought to the “S4” state but have been determined to be in the “S5” state. The data D_01_S5_j is data in which bits of cell transistors MT that had been brought to the “S1” state but have been determined to be in the “S0” state are masked, and does not contain information specifying the bits of the cell transistors MT that had been brought to the “S1” state but have been determined to be in the “S0” state.

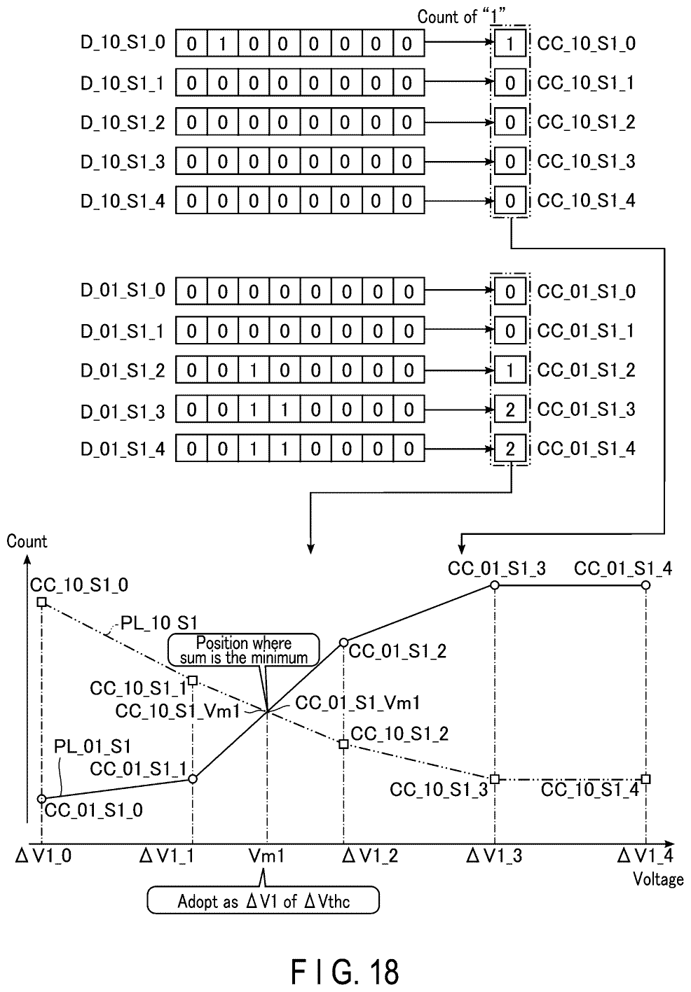

As illustrated in FIG. 18, a count CC_10_S1_j is generated from the data D_10_S1_j with respect to each of the cases where j takes one of 0 to 4. The count CC_10_Sp_j is the number of items of “1” data in the data D_10_Sp_j, that is, the number of 10-changed bits. The count CC_10_Sp_j represents cases where the shift amount ΔVp_j has been used.

A count CC_01_S1_j is generated from the data D_01_S1_j with respect to each of the cases where j takes one of 0 to 4. The count CC_01_Sp_j is the number of items of “1” data in the data D_01_Sp_j, that is, the number of 01-changed bits. The count CC_01_Sp_j represents cases where the shift amount ΔVp_j has been used.

Interpolation of the count CC_10_S1_j is performed with respect to each of the cases where j takes one of 0 to 4. That is, in a two-dimensional space including the count CC_10_S1 on the vertical axis and including the shift amount ΔV1_j on the lateral axis, interpolation of the count CC_10_S1_j and the count CC_10_S1_(j+1) is performed with respect to each of the cases where j takes one of 0 to 3. In one example, interpolation is performed by solving a mathematical equation that expresses a linear line connecting the count CC_10_S1_j and the count CC_10_S1_(j+1) with respect to each of the cases where j takes one of 0 to 3,. Through the interpolation, a plotted line PL_10_Sp is obtained. The plotted line PL_10_Sp includes the count CC_10_Sp_j as a vertex and indicates a relationship in magnitude between the count CC_10_Sp_j and the shift amount ΔVp with respect to each of the cases where j takes all possible values.

Similarly, interpolation is performed for the count CC_01_S1_j with respect to each of the cases where j takes one of 0 to 4. That is, in a two-dimensional space including the count CC_01_S1 on the vertical axis and including the shift amount ΔV1_j on the lateral axis, interpolation of the count CC_01_S1_j and the count CC_01_S1_(j+1) is performed with respect to each of the cases where j takes one of 0 to 3. In one example, interpolation is performed by solving a mathematical equation that expresses a linear line connecting the count CC_01_S1_j and the count CC_01_S1_(j+1) with respect to each of the cases where j takes one of 0 to 3. Through the interpolation, a plotted line PL_01_S1 is obtained. The plotted line PL_01_Sp includes the count CC_01_Sp_j as a vertex and indicates a relationship in magnitude between the count CC_01_Sp_j and the shift amount ΔVp with respect to each of the cases where j takes all possible values.

Based on the plotted lines PL_10_S1 and PL_01_S1, a sum of the counts CC_10_S1_v and CC_01_S1_v is calculated with respect to various shift amounts v. Subsequently, a count CC_10_S1_Vm1 and a count CC_01_S1_Vm1 that form the minimum sum is found. A shift amount Vm1 is adopted as the shift amount ΔV1 of the shift amount group ΔVthc.

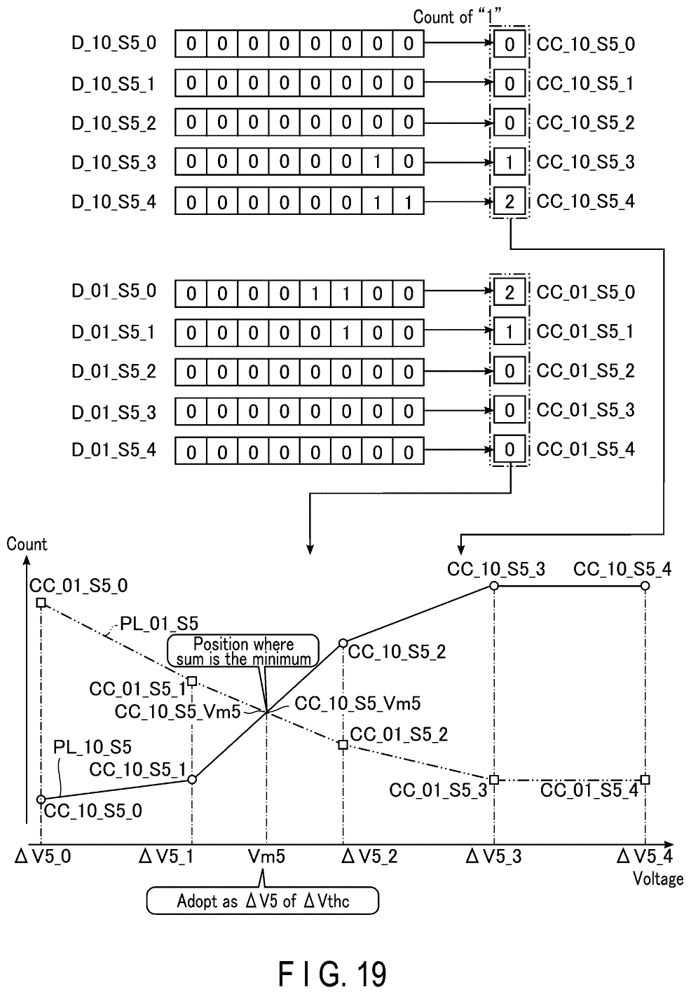

As illustrated in FIG. 19, a count CC_10_S5_j is generated from the data D_10_S5_j with respect to each of the cases where j takes one of 0 to 4. The count CC_01_S5_j is generated from the data D_01_S5_j with respect to each of the cases where j takes one of 0 to 4.

Interpolation of the count CC_10_S5_j is performed by the same method as that described above with reference to FIG. 18 with respect to each of the cases where j takes one of 0 to 4. Through the interpolation, a plotted line PL_10_S5 that includes the counts CC_10_S5_0 to CC_10_S5_j as the vertices is obtained.

Interpolation of the count CC_01_S5_j is performed by the same method as that described above with reference to FIG. 18 with respect to each of the cases where j takes one of 0 to 4. Through the interpolation, a plotted line PL_01_S5 that includes the counts CC_01_S5_0 to CC_01_S5_j as the vertices is obtained.

Based on the plotted lines PL_10_S5 and PL_01_S5, a sum of the counts CC_10_S5_v and CC_01_S5_v is calculated with respect to various shift amounts v. Subsequently, a count CC_10_S5_Vm5 and a count CC_01_S5_Vm5 that form the minimum sum is found. The shift amount Vm5 is adopted as the shift amount ΔV5 of the shift amount group ΔVthc.

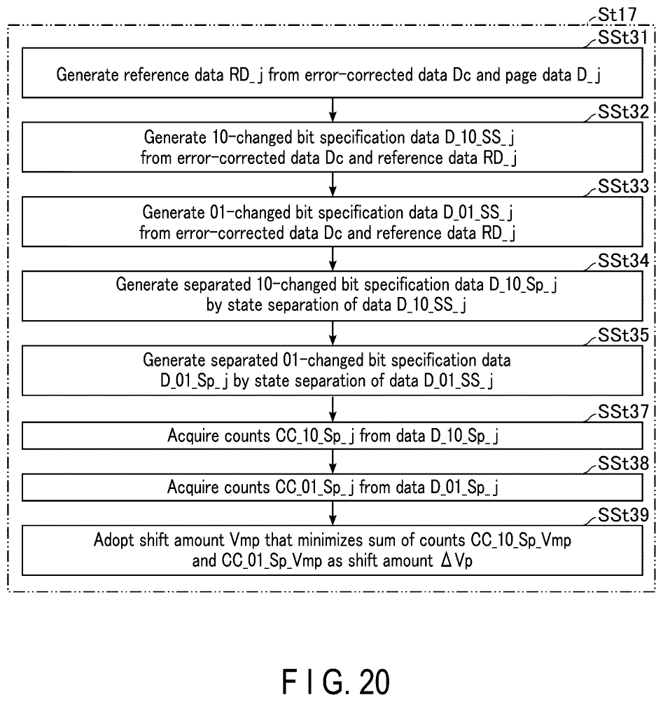

FIG. 20 illustrates a flow of an operation of the memory system according to the second embodiment. FIG. 20 illustrates a sub-flow of step St17 (or, the second-type shift amount estimation) in the flow of FIG. 6, and illustrates an operation performed by the memory controller 10, in particular, the shift amount estimation unit 33.

As illustrated in FIG. 20, the memory controller 10 generates reference data RD_j by a logical operation of the error-corrected data Dc and the page data D_j with respect to each of the cases where j takes one of 0 to 4 (SSt31).

The memory controller 10 generates 10-changed bit specification data D_10_SS_j by a logical operation of the error-corrected data Dc and the reference data RD_j with respect to each of the cases where j takes one of 0 to 4 (SSt32).

The memory controller 10 generates 01-changed bit specification data D_01_SS_j by a logical operation of the error-corrected data Dc and the reference data RD_j with respect to each of the cases where j takes one of 0 to 4 (SSt33). Step SSt33 may be performed prior to step SSt32.

The memory controller 10 generates separated 10-changed bit specification data D_10_Sp_j by state separation on the data D_10_SS_j with respect to each of the cases where p takes all possible values based on the selected page and with respect to each of the cases where j takes one of 0 to 4 (step SSt34). In the case where the selected page is a lower page, data D_10_S1_j and D_10_S5_j are generated with respect to each of the cases where j takes one of 0 to 4. In the case where the selected page is a middle page, data D_10_S2_j, data D_10_S4_j, and data D_10_S6_j are generated with respect to each of the cases where j takes one of 0 to 4. In the case where the selected page is an upper page, data D_10_S3_j and data D_10_S7_j are generated with respect to each of the cases where j takes one of 0 to 4.

The memory controller 10 generates separated 01-changed bit specification data D_01_Sp_j by state separation on the data D_01_SS_j with respect to each of the cases where p takes all possible values based on the selected page and with respect to each of the cases where j takes one of 0 to 4 (step SSt35). In the case where the selected page is a lower page, data D_01_S1_j and D_01_S5_j are generated with respect to each of the cases where j takes one of 0 to 4. In the case where the selected page is a middle page, data D_01_S2_j, data D_01_S4_j, and data D_01_S6_j are generated with respect to each of the cases where j takes one of 0 to 4. In the case where the selected page is an upper page, data D_01_S3_j and data D_01_S7_j are generated with respect to each of the cases where j takes one of 0 to 4.

Step SSt35 may be performed prior to step SSt34.

The memory controller 10 acquires a count CC_10_Sp_j from the data D_10_Sp_j with respect to each of the cases where p takes all possible values based on the selected page and with respect to each of the cases where j takes one of 0 to 4 (SSt37). In the case where the selected page is a lower page, counts CC_10_S1_j and CC_10_S5_j are acquired with respect to each of the cases where j takes one of 0 to 4. In the case where the selected page is a middle page, counts CC_10_S2_j, CC_10_S4_j, and CC_10_S6_j are acquired with respect to each of the cases where j takes one of 0 to 4. In the case where the selected page is an upper page, counts CC_10_S3_j and CC_10_S7_j are acquired with respect to each of the cases where j takes one of 0 to 4.

The memory controller 10 acquires a count CC_01_Sp_j from the data D_01_Sp_j with respect to each of the cases where p takes all possible values based on the selected page and with respect to each of the cases where jtakes one of 0 to 4 (SSt38). In the case where the selected page is a lower page, counts CC_01_S1_j and CC_01_S5_j are acquired with respect to each of the cases where j takes one of 0 to 4. In the case where the selected page is a middle page, counts CC_01_S2_j, CC_01_S4_j, and CC_01_S6_j are acquired with respect to each of the cases where j takes one of 0 to 4. In the case where the selected page is an upper page, counts CC_01_S3_j and CC_01_S7_j are acquired with respect to each of the cases where j takes one of 0 to 4.

Step SSt38 may be performed prior to step SSt37.

The memory controller 10 adopts a shift amount Vmp that minimizes a sum of the counts CC_10_Sp_Vmp and CC_01_Sp_Vmp as the shift amount ΔVp with respect to each of the cases where p takes all possible values based on the selected page (SSt39).

In the case where the selected page is a lower page, a shift amount Vm1 that minimizes a sum of the counts CC_10_S1_Vm1 and CC_01_S1_Vm1 is found. The found shift amount Vm1 is adopted as the shift amount ΔV1. A shift amount Vm5 that minimizes a sum of the counts CC_10_S5_Vm5 and CC_01_S5_Vm5 is found. The found shift amount Vm5 is adopted as the shift amount ΔV5.

In the case where the selected page is a middle page, a shift amount Vm2 that minimizes a sum of the counts CC_10_S2_Vm2 and CC_01_S2_Vm2 is found. The found shift amount Vm2 is adopted as the shift amount ΔV2. A shift amount Vm4 that minimizes a sum of the counts CC_10_S4_Vm4 and CC_01_S4_Vm4 is found. The found shift amount Vm4 is adopted as the shift amount ΔV4. A shift amount Vm6 that minimizes a sum of the counts CC_10_S6_Vm6 and CC_01_S6_Vm6 is found. The found shift amount Vm6 is adopted as the shift amount ΔV6.

In the case where the selected page is an upper page, a shift amount Vm3 that minimizes a sum of the counts CC_10_S3_Vm3 and CC_01_S3_Vm3 is found. The found shift amount Vm3 is adopted as the shift amount ΔV3. A shift amount Vm7 that minimizes a sum of the counts CC_10_S7_Vm7 and CC_01_S7_Vm7 is found. The found shift amount Vm7 is adopted as the shift amount ΔV7.

By step SSt39, the shift amount group ΔVthc is obtained.

### 2. 2. Advantages

According to the second embodiment, the number of 10-changed bits and the number of 01-changed bits are acquired for each value of j from a plurality of items of page data D_j obtained using a plurality of different shift amount groups ΔVth, and a shift amount group ΔVthc is estimated based on a shift amount that minimizes a sum of the number of 10-changed bits and the number of 01-changed bits. It is thus possible to obtain the shift amount group ΔVthc without referring to a shift amount correspondence table, which is required in the case of estimating a shift amount from a ratio between memory cell counts E_01_Sp and E_10_Sp using error-corrected data Dc.

According to the second embodiment, page data D_j is required with respect to a plurality of values of j in the second-type shift amount estimation. However, the data D_j is acquired during the first-type shift amount estimation. It is thus possible to estimate the shift amount group ΔVthc simply by storing data acquired for another purpose until completion of generation of reference data RD_j in the second-type shift amount estimation, without performing an additional data read.

### 2. 3. Modification

A modification of the second embodiment differs from the basic aspect of the second embodiment in terms of the second-type shift amount estimation. In the modification, the memory controller 10 keeps storing the separated page data DSp_j obtained at step SSt8, instead of continuing to store the page data D_j for the second-type shift amount estimation, with respect to each of the cases where p takes all possible values based on the selected page and with respect to each of the cases where j takes one of 0 to 4. The memory controller 10 already stores the data DSp_j in the separated page data storage unit 37 at the start of step SSt17 (or, second-type shift amount estimation) with respect to each of the cases where p takes all possible values based on the selected page and with respect to each of the cases where j takes one of 0 to 4.

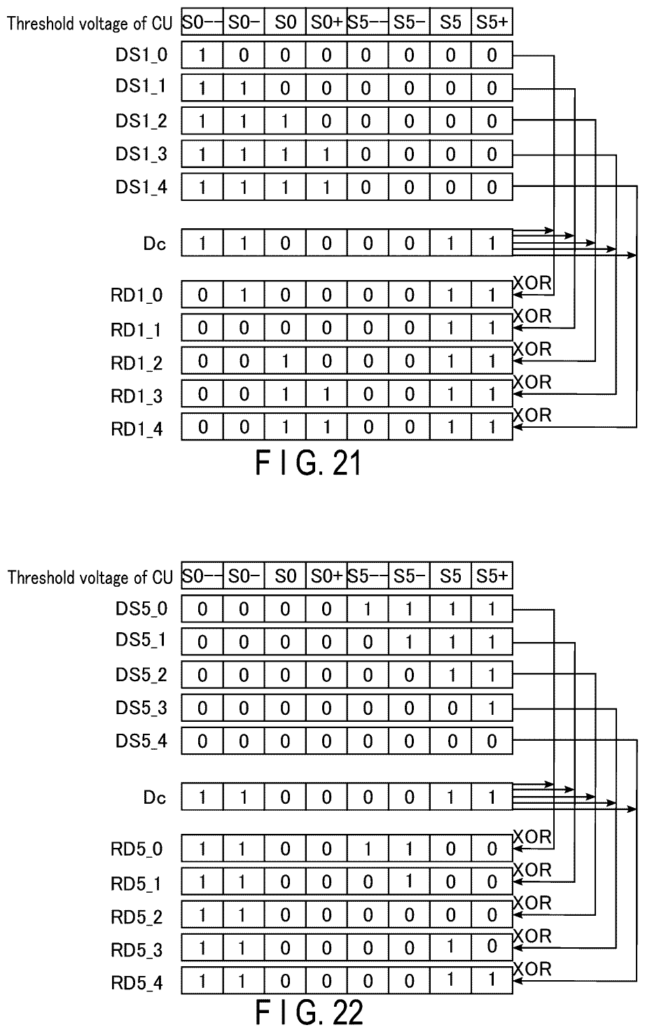

Each of FIGS. 21 to 26 illustrates a concept of second-type shift amount estimation by the memory system according to the modification of the second embodiment. In FIGS. 21 to 26, estimation of shift amounts ΔV1 and ΔV5 of lower pages is illustrated as a representative.

The memory controller 10 keeps storing the separated page data DS1_j and DS5_j stored in the separated page data storage unit 37 at step SSt8 until completion of separated page data DS1_j and DS5_j used at step St17 (or, second-type shift amount estimation) with respect to each of the cases where j takes one of 0 to 4.

As illustrated in FIG. 21, reference data RD1_j is generated by an XOR operation of the error-corrected data Dc and the separated page data DS1_j with respect to each of the cases where j takes one of 0 to 4.

As illustrated in FIG. 22, reference data RD5_j is generated by an XOR operation of the error-corrected data Dc and the separated page data DS5_j with respect to each of the cases where j takes one of 0 to 4.

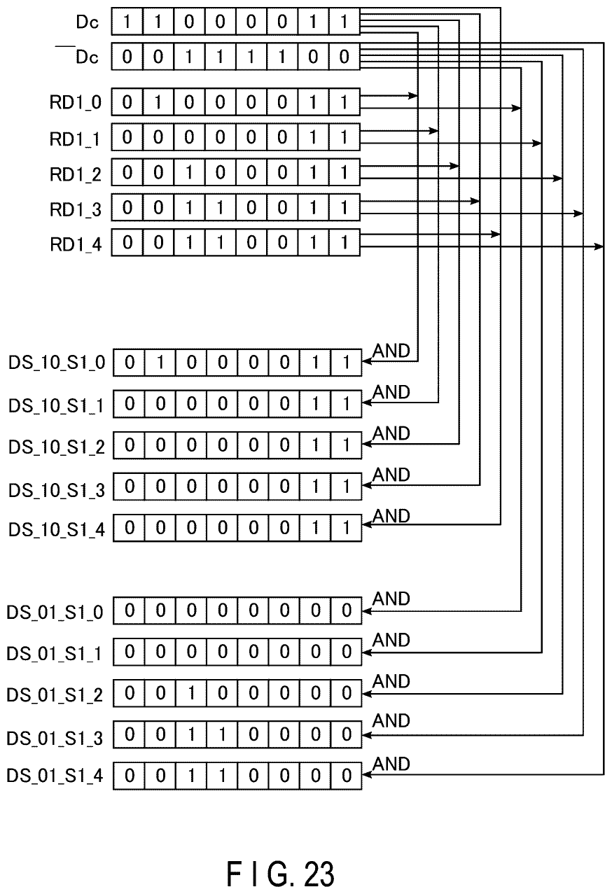

As illustrated in FIG. 23, data DS_10_S1_j is generated by an AND operation of the error-corrected data Dc and the reference data RD1_j with respect to each of the cases where j takes one of 0 to 4. The data DS_10_Sp_j contains information specifying 10-changed bits that occur only at a boundary between the “Sp” state and the “Sp-1” state in the separated page data DSp_j.

Data DS_01_S1_j is generated by an AND operation of negation of the error-corrected data Dc and the reference data RD1_j with respect to each of the cases where j takes one of 0 to 4. The data DS_01_Sp_j contains information specifying 01-changed bits that occur only at a boundary between the “Sp” state and the “Sp-1” state in the separated page data DSp_j.

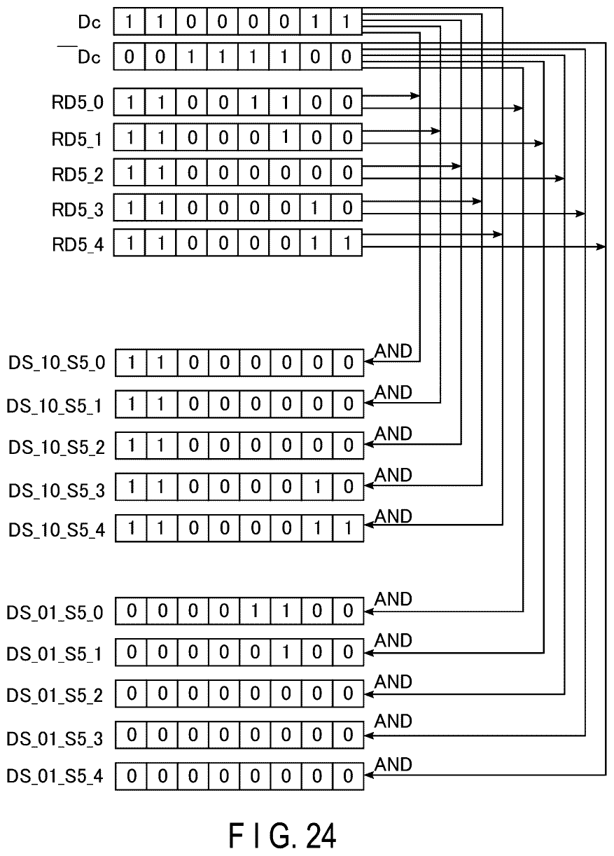

As illustrated in FIG. 24, data DS_10_S5_j is generated by an AND operation of the error-corrected data Dc and the reference data RD5 j, with respect to each of the cases where j takes one of 0 to 4. Data DS_01_S5_j is generated by an AND operation of negation of the error-corrected data Dc and the reference data RD5 j with respect to each of the cases where j takes one of 0 to 4.

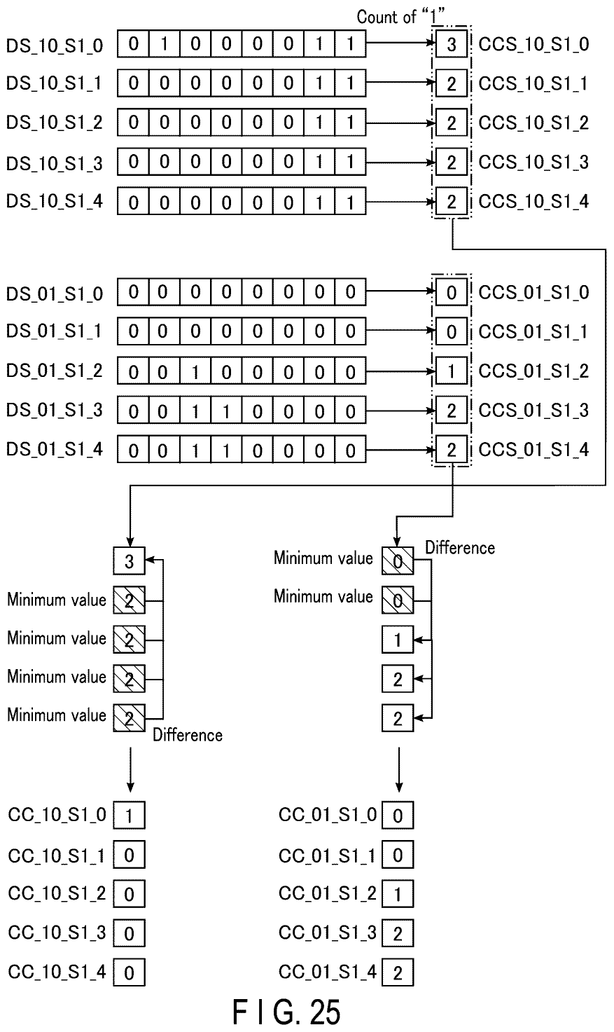

As illustrated in FIG. 25, a count CCS_10_S1_j is generated from the data DS_10_S1_j with respect to each of the cases where j takes one of 0 to 4. The count CCS_10_Sp_j is the number of items of “1” data in the data DS_10_Sp_j. A count CCS_01_S1_j is generated from the data DS_01_S1_j with respect to each of the cases where j takes one of 0 to 4. The count CCS_01_Sp_j is the number of items of “1” data in the data DS_01_Sp_j.

For the four values other than the minimum one of the counts CCS_10_S1_0, CCS_10_S1_1, CCS_10_S1_2, CCS_10_S1_3, and CCS_10_S1_4, a difference from the minimum value is calculated. Thereby, the counts CC_10_S1_0, CC_10_S1_1, CC_10_S1_2, CC_10_S1_3, and CC_10_S1_4 are obtained by the same number as the number described above with reference to FIG. 18.

For the four values other than the minimum one of the counts CCS_01_S1_0, CCS_01_S1_1, CCS_01_S1_2, CCS_01_S1_3, and CCS_01_S1_4, a difference from the minimum value is calculated. Thereby, the same counts CC_01_S1_0, CC_01_S1_1, CC_01_S1_2, CC_01_S1_3, and CC_01_S1_4 are obtained by the same number as the number described above with reference to FIG. 18.

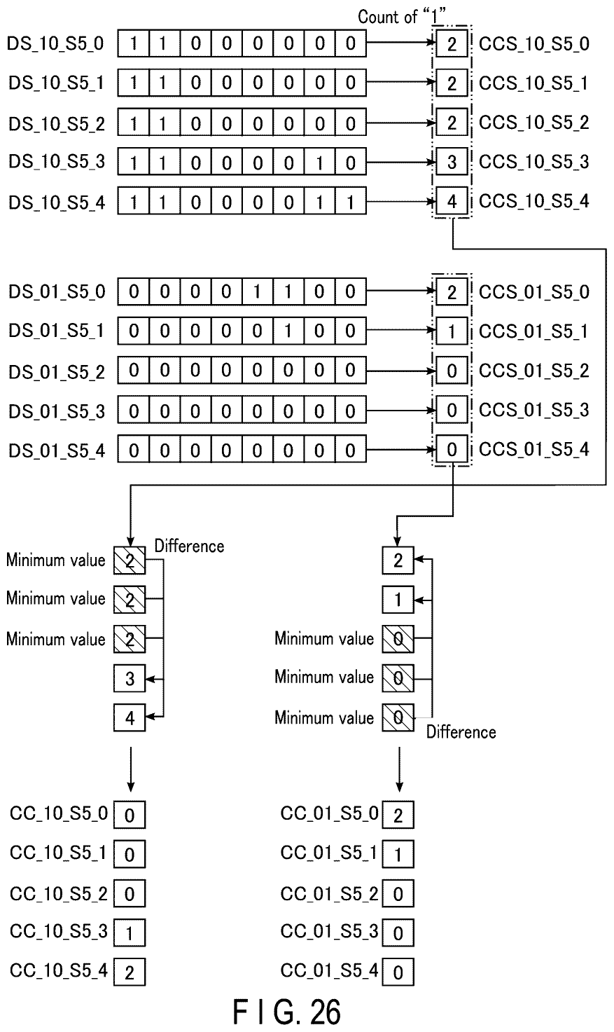

As illustrated in FIG. 26, a count CCS_10_S5_j is generated from the data DS_10_S5_j, with respect to each of the cases where j takes one of 0 to 4. A count CCS_01_S5_j is generated from the data DS_01_S5_j with respect to each of the cases where j takes one of 0 to 4.

For the four values other than the minimum one of the counts CCS_10_S5_0, CCS_10_S5_1, CCS_10_S5_2, CCS_10_S5_3, and CCS_10_S5_4, a difference from the minimum value is calculated. Thereby, the counts CC_10_S5_0, CC_10_S5_1, CC_10_S5_2, CC_10_S5_3, and CC_10_S5_4 are obtained by the same number as the number described above with reference to FIG. 19.

For the four values other than the minimum one of the counts CCS_01_S5_0, CCS_01_S5_1, CCS_01_S5_2, CCS_01_S5_3, and CCS_01_S5_4, a difference from the minimum value is calculated. Thereby, the counts CC_01_S5_0, CC_01_S5_1, CC_01_S5_2, CC_01_S5_3, and CC_01_S5_4 are obtained by the same number as the number described above with reference to FIG. 19.

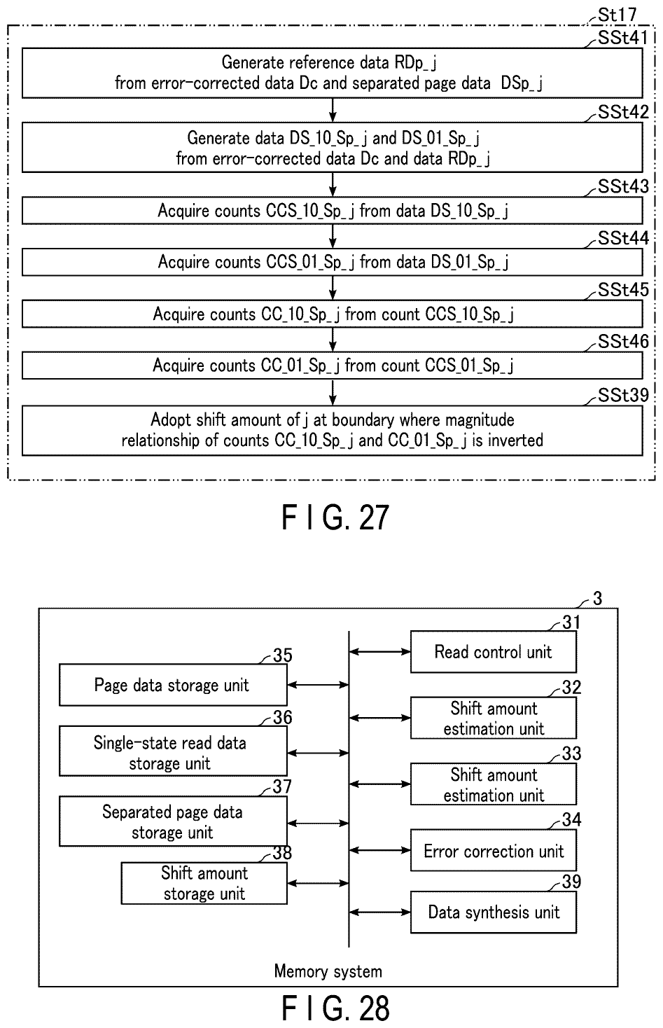

FIG. 27 illustrates a flow of an operation of a memory system according to a modification of the second embodiment. FIG. 27 illustrates a sub-flow of step St17 (or, the second-type shift amount estimation) in the flow of FIG. 6, and illustrates an operation performed by the memory controller 10, in particular, the shift amount estimation unit 33, is illustrated.

As illustrated in FIG. 27, the memory controller 10 generates reference data RDp_j by an XOR operation of the error-corrected data Dc and the separated page data DSp_j with respect to each of the cases where p takes all possible values based on the selected page and with respect to each of the cases where j takes one of 0 to 4 (SSt41).

The memory controller 10 generates data DS_10_Sp_j and data DS_01_Sp_j by a logical operation of the error-corrected data Dc and the reference data RDp j with respect to each of the cases where p takes all possible values based on the selected page and with respect to each of the cases where j takes one of 0 to 4 (SSt42).

The memory controller 10 acquires a count CCS_10_Sp_j from the data DS_10_Sp_j with respect to each of the cases where p takes all possible values based on the selected page and with respect to each of the cases where j takes one of 0 to 4 (SSt43).

The memory controller 10 acquires a count CCS_01_Sp_j from the data DS_01_Sp_j with respect to each of the cases where p takes all possible values based on the selected page and with respect to each of the cases where j takes one of 0 to 4 (SSt44).

Step SSt44 may be performed prior to step SSt43.

The memory controller 10 acquires a count CC_10_Sp_j from the count CCS_10_Sp_j with respect to each of the cases where p takes all possible values based on the selected page and with respect to each of the cases where j takes one of 0 to 4 (SSt45).

The memory controller 10 acquires a count CC_01_Sp_j from the count CCS_01_Sp_j with respect to each of the cases where p takes all possible values based on the selected page and with respect to each of the cases where j takes one of 0 to 4 (SSt46).

Step SSt46 may be performed prior to step SSt45.

Step SSt46 follows step SSt39.

According to the modification, the single-state read data storage unit 36 does not need to keep storing the single-state read data DkR until the second-type shift amount estimation.

### 3. Third Embodiment

A third embodiment is additionally applied to the first or second embodiment. The hardware configuration of a memory system 3 according to the third embodiment is the same as that of the first embodiment.

### 3. 1. Operation

FIG. 28 illustrates an example of functional blocks during operation of the memory system according to a third embodiment. As illustrated in FIG. 28, the memory system 3 includes a data synthesizing unit 39 during operation of the memory system 3 in addition to the functional blocks in the first embodiment.

The data synthesizing unit 39 synthesizes a part of page data and a part of intermediate data based on the page data to generate different page data.

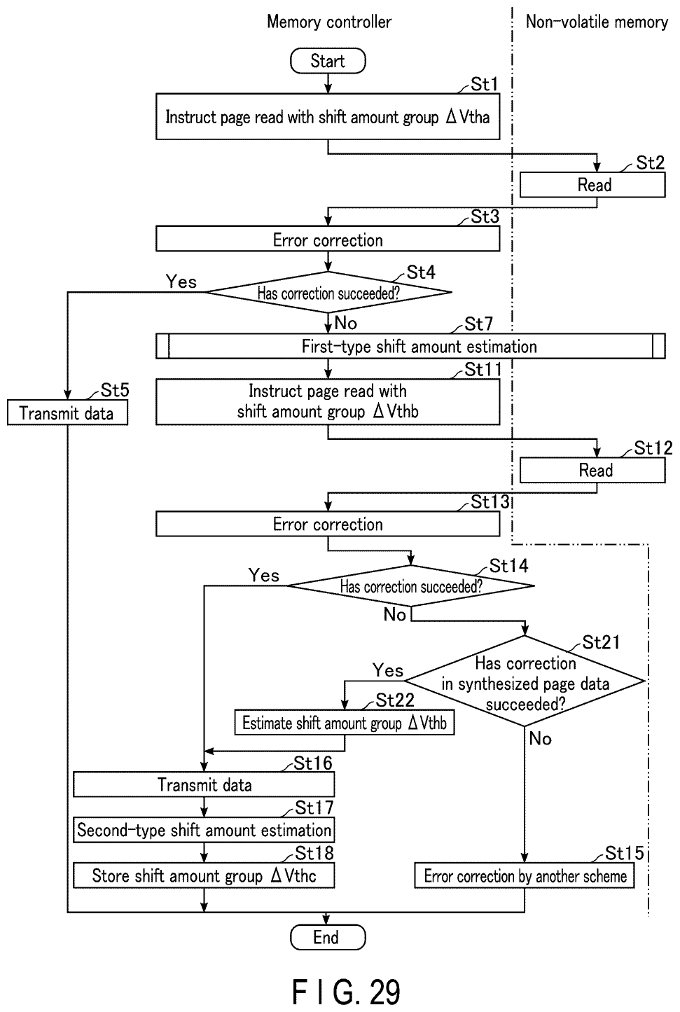

FIG. 29 illustrates a flow of an operation of the memory system according to the third embodiment. The flow of FIG. 29 is started if the memory controller 10 receives a data read request from the host device 2 and specifies a page from which data is to be read to execute the data read request.

The memory controller 10 keeps storing the separated page data DSp_j obtained at step SSt8 with respect to each of the cases where p takes all possible values based on the selected page and with respect to each of the cases where j takes one of 0 to 4. The memory controller 10 already stores the data DSp_j in the separated page data storage unit 37 at the start of step St17 (second-type shift amount estimation) with respect to each of the cases where p takes all possible values based on the selected page and with respect to each of the cases where j takes one of 0 to 4.

If the error correction fails (St14; No), the memory controller 10 attempts to correct an error in the synthesized page data using the data synthesizing unit 39 and the error correction unit 34 (St21). The synthesized page data is formed of a combination of parts of separated page data DSp_j. Further details of the synthesized page data will be given later. If the error correction fails (St21; No), the flow advances to step St15.

If the error correction succeeds (St21; Yes), error-corrected data Dc is obtained, and the flow advances to step St16. The memory controller 10 estimates a shift amount group ΔVthb from the error-corrected data Dc (St22). The shift amount group ΔVthb obtained at step St7 is updated by the shift amount group ΔVthb obtained at step St22. Further details of the estimation of the shift amount group ΔVthb will be given later, together with those of the synthesized page data. Step St22 follows step St16.

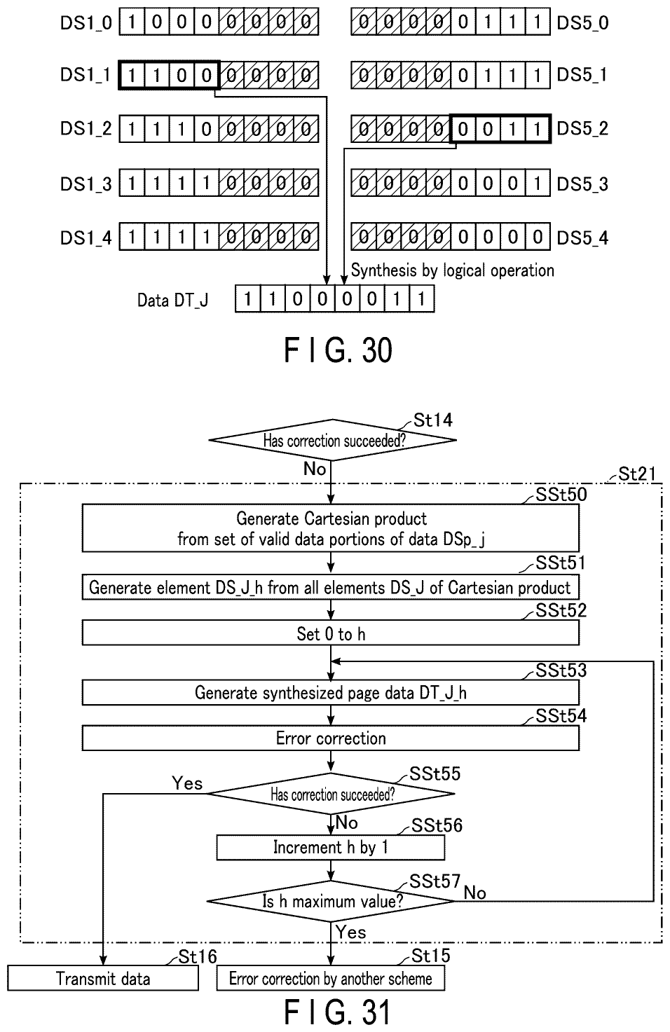

FIG. 30 illustrates an example of synthesized page data, and illustrates a concept of an operation by the memory system according to the third embodiment. A case of reading lower pages is illustrated as a representative.

Separated page data DS1_j includes a valid data portion only for cell transistors MT with a threshold voltage at which the cell transistors MT are ON upon receiving a read voltage V1.

On the other hand, separated page data DS5_j includes a valid data portion only for cell transistors MT that are OFF upon receiving a read voltage V5. The valid data portion of the data DS1_j and the valid data portion of the data DS5_j are synthesized to generate synthesized page data. The synthesized page data contains, in the bits of cell transistors MT with a threshold voltage in the vicinity of a read voltage V1, the same information as the data DS1_j, and contains, in the bits of cell transistors MT with a threshold voltage in the vicinity of the read voltage V5, information same as the data DS5_j. That is, data DSp1_j1 on a value j (j1) and data DSp2_j2 on another value j (j2) are synthesized to generate synthesized page data DT_J. Here, J is a set of j1 and j2. The values of j1 and j2 may be either the same or different. FIG. 30 illustrates an example of data DT_J formed of a valid data portion of the data DS1_1 and a valid data portion of the data DS5_2.

The synthesized page data can be generated by any logical operation. In an example, the logical operation is either an OR operation or an XOR operation.

In the case of a middle page, a valid data portion of data DS2_j1, a valid data portion of data DS4_j2, and a valid data portion of data DS6_j3 are synthesized. The value of j3 may be the same as or different from those of j1 and j2. In the case of an upper page, a valid data portion of the data DS3_j1 and a valid data portion of the data DS7_j2 are synthesized.

FIG. 31 illustrates a flow of an operation of the memory system according to the third embodiment. FIG. 31 illustrates a sub-flow of step St21 of the flow of FIG. 29.

As illustrated in FIG. 31, the memory controller 10 generates a Cartesian product from a set of specific valid data portions of the separated page data DSp_j (SSt50). That is, a set (or, array) of valid data portions DESp_j is generated by generating, for each value of p, valid data portion DESp_j with respect to each of the cases where p takes all possible values based on the selected page and with respect to each of the cases where j takes one of 0 to 4. Subsequently, a single element of the Cartesian product is generated from respective valid data portions DESp_j p with all values of p. That is, five elements DSp1_Sp2_j1_0, DSp1_Sp2_j1_1, DSp1_Sp2_j1_2, DSp1_Sp2_j1_3, and DSp1_Sp2_j1 4 are generated from the valid data portion DESp1_j for a single value of p and for a single value of j and from the valid data portion DESp2_j for the remaining values of p and for all possible values of j. A specific example of a lower page will be described below. That is, elements DS1_S5_0_0, DS1_S5_0_1, DS1_S5_0_2, DS1_S5_0_3, and DS1_S5_0_4 are respectively generated from the valid data portion DES1_0 and the valid data portions DES5_0, DES5_1, DES5_2, DES5_3, and DES5_4. Similarly, the elements DS1_S5_1_j, DS1_S5_2_j, DS1_S5_3_j, and DS1_S5_4_j are generated with respect to each of the cases where j takes one of 0 to 4. The generated elements are elements DS_J of the Cartesian product.

This can be rephrased as follows. That is, p valid data portion groups DEGSp are generated with respect to each of the cases where p takes all possible values. The valid data portion group DEGSp includes five valid data portions DESp_0, DESp_1, DESp_2, DESp_3, and DESp_4. A single element DS_J is generated from the valid data portion DESp_0, DESp_1, DESp_2, DESp_3, or DESp_4 of each of the p valid data portion groups DEGSp. Accordingly, assuming a case where the elements of an array of all possible values of p (i.e., (p1, p2, p3, . . . )) are parameters and each of the parameters includes five valid data portions DESp_j, the Cartesian product is formed of a combination of all possible values of each of the parameters.

For the generation of the Cartesian product, synthesized page data DT_J need not be actually generated, and it suffices that information specifying each element DS_J of the Cartesian product is generated. For example, by generating an index uniquely specifying the combination of the value of p and the value of j, it is possible to specify, based on the index, valid data portions of which data DESp_j are to be combined at the time of generation of synthesized page data.

As illustrated in FIG. 31, the memory controller 10 generates the element DS_J_h by adding a value h to all the elements DS_J of the Cartesian product (SSt51). Here, h is either 0 or a positive integer, and indicates an order of preference of addition target elements DS_J. A smaller value of h indicates a higher order of preference. The order of preference may be determined by a predetermined rule. The element DS_J_h is given a higher order of preference if it can be expected that synthesized page data DT_J_h generated from the element DS_J_h is expected to succeed in error correction with a higher probability. An example will be given below.

The closer the shift amount used by j is to the shift amounts ΔV1 to ΔV7 included in the shift amount group ΔVthb, the higher the priority given to the element DS_J.

In the case where the write data is randomized, the closer the ON-cell count based on the page data D_j obtained by j is to the expected value, the higher the priority given to the element DS_J. Since the numbers of cell transistors MT in the respective states are expected to be approximately uniform as a result of randomization, as described above with reference to FIG. 4, it is possible to estimate an expected value of the ON-cell count as a result of the first-type shift amount estimation.

If two local minimum points are found in the first-type shift amount estimation, an element DS_J closer to the local minimum point that was not used for calculation of one of the shift amounts ΔV1 to ΔV7 included in the shift amount group ΔVthb is given a higher priority.

The memory controller 10 sets 0 to h (SSt52).

The memory controller 10 generates the synthesized page data DT_J_h (SSt53).

The memory controller 10 attempts to correct an error in the data DT_J_h using the error correction unit 34 (SSt54).

If the error correction fails (SSt55; No), the memory controller 10 increments h by 1 (SSt56). If h is the maximum value (SSt57; Yes), the sub-flow is complete, and the flow of FIG. 29 advances to step St15. The maximum value of h may have any magnitude. In an example, the maximum value of h is equal to the number of elements DS_J of the Cartesian product. In another example, the maximum value of h is smaller than the number of elements DS_J of the Cartesian product.

If h is not the maximum value (SSt57; No), the flow continues to step SSt53.

If the error correction succeeds (SSt55; Yes), the sub-flow is complete, and the flow of FIG. 29 advances to step St16. As a result of the success of the error correction, data Dc is obtained.

If the error correction of the synthesized page data DT_J_h succeeds, a shift amount group ΔVthb is estimated based on the data DT_J_h at step St22. That is, in the case where, for example, the selected page is a lower page, if the data DT_J_h is formed of a valid data portion of the separated page data DS1_j1 and a valid data portion of the separated page data DS2_j2, the shift amount group ΔVthb includes a shift amount ΔV1 in the shift amount group ΔVth_j1 and a shift amount ΔV5 in the shift amount group ΔVth_j2.

### 3. 2. Advantages

According to the third embodiment, it is possible to provide a memory system that reads data with high efficiency, as described below.

Even if error correction of page data obtained using the shift amount group ΔVthb obtained by the first-type shift amount estimation fails, error correction may succeed through use of a shift amount group ΔVthb slightly different from the shift amount group ΔVthb.

The memory system 3 according to the third embodiment generates synthesized page data DT_J if error correction of the page data obtained using the shift amount group ΔVthb obtained by the first-type shift amount estimation fails. The synthesized page data DT_J is formed of a combination of parts of the shift amount group ΔVth with various magnitudes obtained in the course of the first-type shift amount estimation. Thus, error correction of the obtained synthesized page data may succeed depending on the combination. A high level of error correction as in step St15 requires a long period of time for execution. It is thus possible to efficiently read data if error correction succeeds prior to execution of a high level of error correction. The separated page data DSp_j, which provides a portion of the synthesized page data, is acquired during the first-type shift amount estimation. It is thus possible to generate synthesized page data simply by storing data acquired for another purpose until completion of generation of synthesized page data, without performing an additional data read.

### 3. 3. Modification

In a modification, the memory controller 10 keeps storing page data D_j and single-state read data DkR until step St21, instead of continuing to store separated page data DSp_j until step St21, performs state separation at step St21, thereby generating separated page data DSp_j.

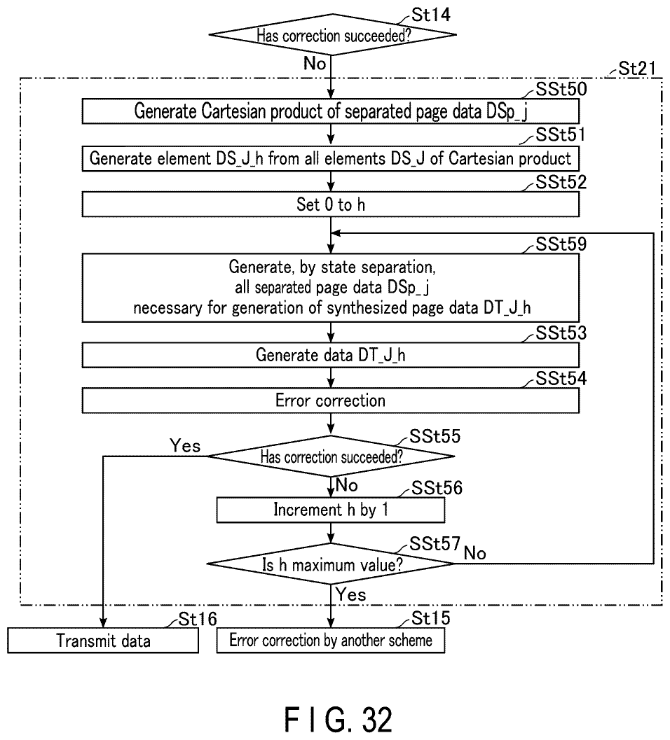

FIG. 32 illustrates a flow of an operation of a memory system according to a modification of the third embodiment. FIG. 32 illustrates a sub-flow of step St21 of the flow of FIG. 29. At the start of step St21, page data D_j is already stored, with respect to each of the cases where j takes one of 0 to 4, and single-state read data DkR is already stored.

As illustrated in FIG. 32, after step SSt52, the memory controller 10 generates all the separated page data DSp_j necessary for generation of the synthesized page data DT_J_h (SSt59). If the data DT_J_h is formed of a valid data portion of the data DS1_1 and a valid data portion of the data DS5_2, the memory controller 10 generates data DS1_1 from the page data D_j using the single-state read data D3R, and generates data DS5_2 from the page data D_j using the data D3R. Every time the data DSp_j is generated, it is stored in the separated page data storage unit 37. If the necessary data DSp_j at step SSt59 is stored in the separated page data storage unit 37, the stored data DSp_j is used. Step SSt59 follows step SSt53. If h is not the maximum value (SSt57; No), the flow continues to step SSt59.

### 4. Fourth Embodiment

In a fourth embodiment, which is applied to the third embodiment, synthesized page data is generated from a valid data portion generated based on threshold voltages of cell transistors MT of a cell unit CU adjacent to a read target cell unit CU. The hardware configuration of a memory system according to the fourth embodiment is the same as that of the first embodiment (FIG. 4). The configuration of functional blocks during operation of the memory system according to the fourth embodiment is the same as that of the third embodiment (FIG. 28).

### 4. 1. Operation

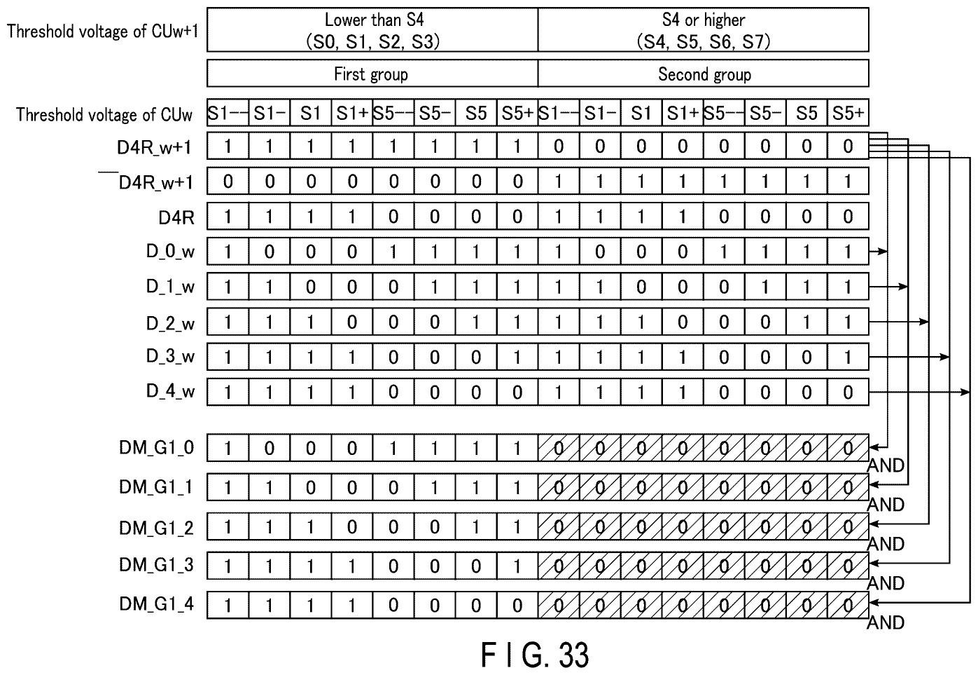

FIGS. 33 to 36 illustrate a concept of a first-type shift amount estimation by the memory system according to the fourth embodiment. In FIGS. 33 to 36, lower pages are illustrated as a representative.

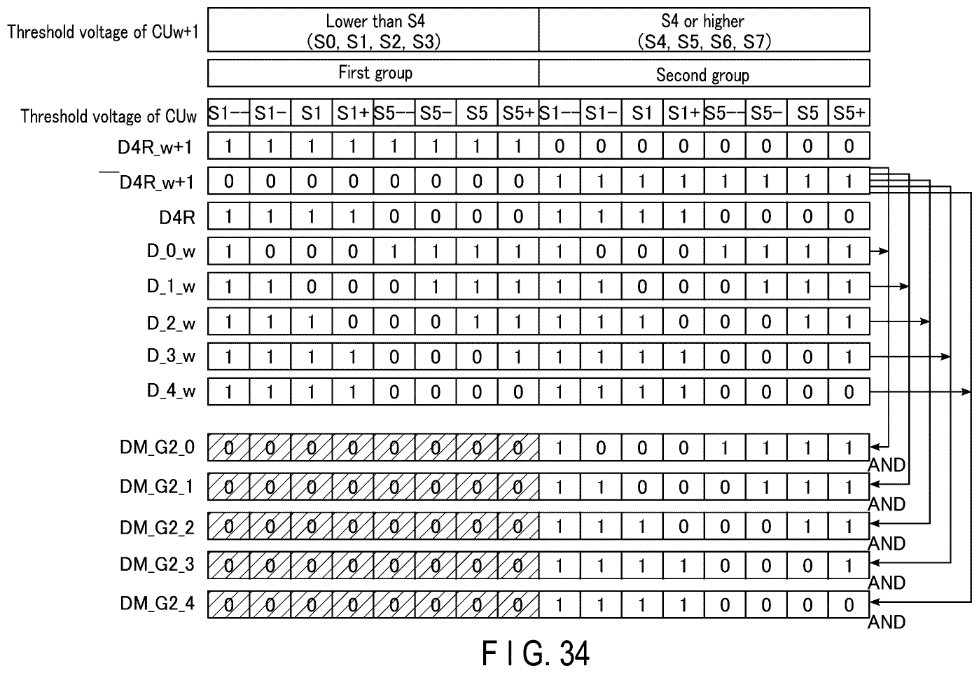

As illustrated in FIGS. 33 and 34, bits of page data D_j_w read from a selected cell unit CUw are masked based on which of a first group and a second group of certain features each bit belongs, with respect to each of the cases where j takes one of 0 to 4. The groups are based on the state of an adjacent cell transistor MTw+1 in an adjacent cell unit CUw+1. The adjacent cell unit CUw+1 is coupled to a conductor CW adjacent to a conductor CW (or, a word line WL) coupled to a selected cell unit CUw on the positive side of the z-axis.

The first group includes bits of a selected cell transistor MTw adjacent to an adjacent cell transistor MTw+1 that is in a lower state than an “Su” state. Here, u is 0 or a positive integer. The second group includes bits of a selected cell transistor MTw adjacent to an adjacent cell transistor MTw+1 that is in the “Su” state or a higher state. In an example, u is 4. In this example, an adjacent cell transistor MTw+1 in the first group includes bits that belong to one of the “S0”, “S1”, “S2”, and “S3” states, and an adjacent cell transistor MTw+1 in the second group includes bits that belong to one of the “S4”, “S5”, “S6”, and “S7” states. The description that follows is based on this example.

Whether the adjacent cell transistor MTw+1 is in a lower state than the “S4” state or in the “S4” or higher state can be known from single-state read data D4R_w+1. The data DkR_w+1 is obtained by a single-state read of the adjacent cell transistor MTw+1 with a read voltage Vk.

For classification into the first or second group, the page data D_j_w is masked by data D4R_w+1 with respect to each of the cases where j takes one of 0 to 4. Through the masking, data DM_G1_j and DM_G2_j are generated with respect to each of the cases where j takes one of 0 to 4. In the data DM_Gt_j, bits belonging to a group other than a t-th group are masked, and bits containing “0” data and belonging to a t-th group contain valid data. Here, t is an integer equal to or greater than 0.

In one example, data DM_G1_j is a logical conjunction of data D_j_w and data D4R_w+1. In one example, data DM_G2_j is a logical conjunction of the data D_j_w and negation of the data D4R_w+1.

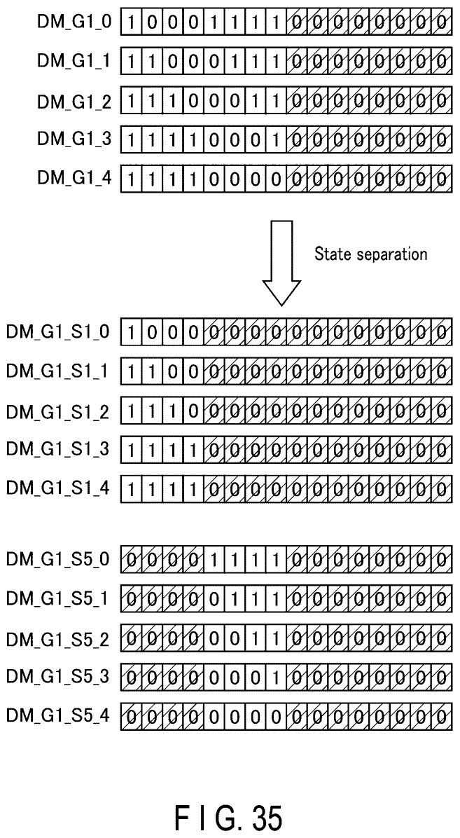

As illustrated in FIG. 35, state separation of the data DM_G1_j is performed using single-state read data D4R with respect to each of the cases where j takes one of 0 to 4. That is, the data DM_G1_j is masked by data D4R with respect to each of the cases where j takes one of 0 to 4. As a result, data DM_G1_S1_j and data DM_G1_S5_j are generated from the data DM_G1_j with respect to each of the cases where j takes one of 0 to 4. The data DM_G1_S1_j contains information of part of the data DM_G1_j that is based on a read with the read voltage V1, and does not contain information of part of the data DM_G1_j that is based on a read with the read voltage V5. The data DM_G1_S5_j contains information of part of the data DM_G1_j that is based on a read with the read voltage V5, and does not contain information of part of the data DM_G1_j that is based on a read with the read voltage V1.

Estimation of the shift amount ΔV1 is performed using the data DM_G1_S1_j. The estimated shift amount ΔV1 is a shift amount that uses a cell transistor MT adjacent to an adjacent cell transistor MTw+1 in a lower state than the “S4” state.

Estimation of the shift amount ΔV5 is performed using the data DM_G1_S5_j. The estimated shift amount ΔV5 is a shift amount that uses a cell transistor MT adjacent to an adjacent cell transistor MTw+1 in a lower state than the “S4”.

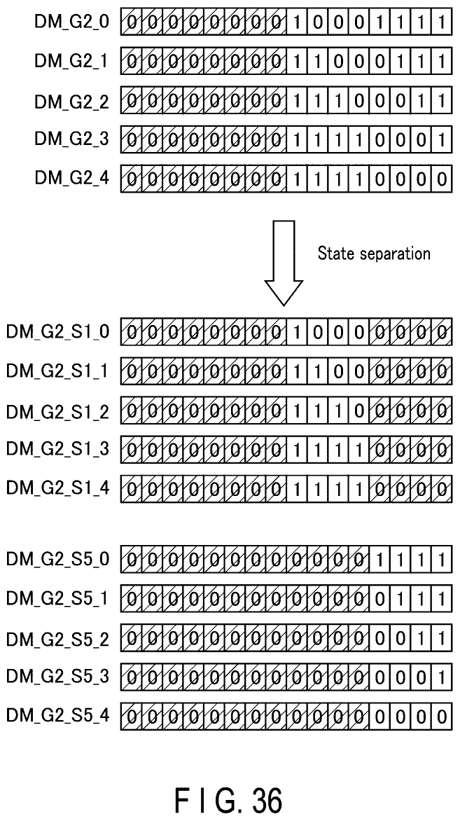

As illustrated in FIG. 36, state separation of the data DM_G2_j is performed using single-state read data D4R with respect to each of the cases where j takes one of 0 to 4. That is, with respect to each of the cases where j takes one of 0 to 4, the data DM_G2_j is masked by data D4R. As a result, data DM_G2_S1_j and data DM_G2_S5_j are generated from the data DM_G2_j with respect to each of the cases where j takes one of 0 to 4. The data DM_G2_S1_j contains information of part of the data DM_G2_j that is based on a read with the read voltage V1, and does not contain information of part of the data DM_G2_j that is based on a read with the read voltage V5. The data DM_G2_S5_j contains information of part of the data DM_G2_j that is based on a read with the read voltage V5, and does not contain information of part of the data DM_G2_j that is based on a read with the read voltage V1.

Estimation of the shift amount ΔV1 is performed using the data DM_G2_S1_j. The estimated shift amount ΔV1 is a shift amount using a cell transistor MT adjacent to an adjacent cell transistor MTw+1 in the “S4” state or a higher state.

Estimation of the shift amount ΔV5 is performed using the data DM_G2_S5_j. The estimated shift amount ΔV5 is a shift amount using a cell transistor MT adjacent to an adjacent cell transistor MTw+1 in the “S4” state or a higher state.

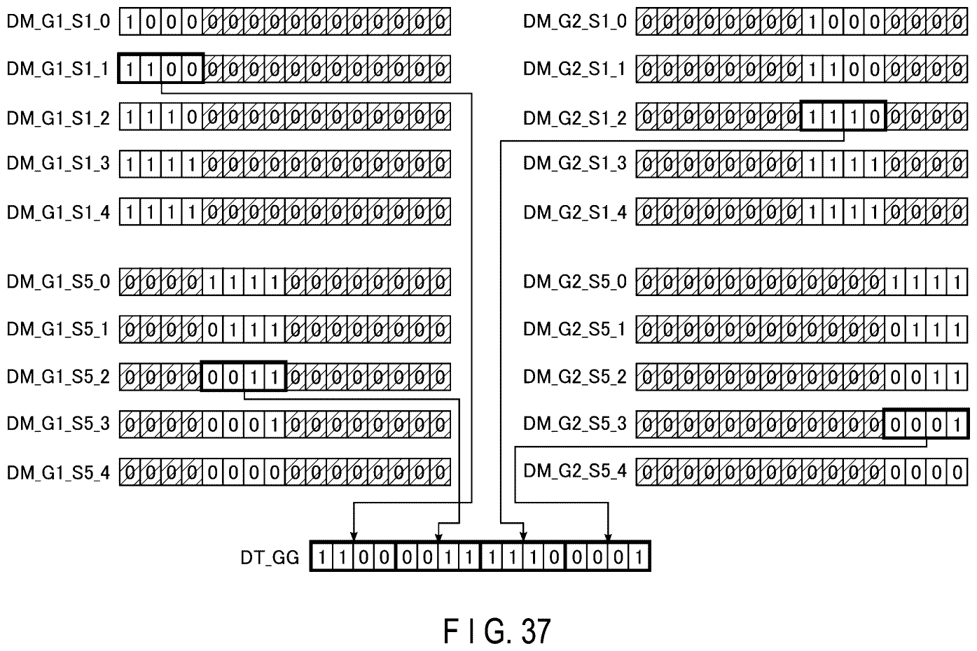

FIG. 37 illustrates an example of synthesized page data, and illustrates a concept of an operation by the memory system according to the fourth embodiment. A lower page is illustrated as a representative. Synthesized page data DT_GG is formed of a valid data portion of one of items of data DM_G1_S1_0 to DM_G1_S1_4, a valid data portion of one of items of data DM_G1_S5_0 to DM_G1_S5_4, a valid data portion of one of items of data DM_G2_S1_0 to DM_G2_S1_4, and a valid data portion of one of items of data DM_G2_S5_0 to DM_G2_S5_4.

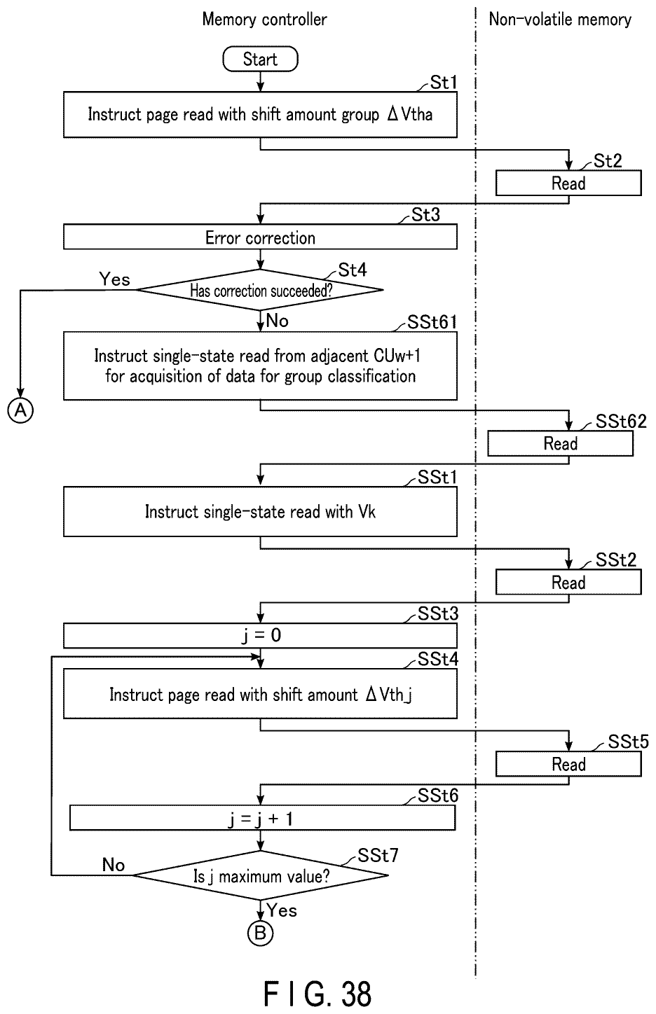

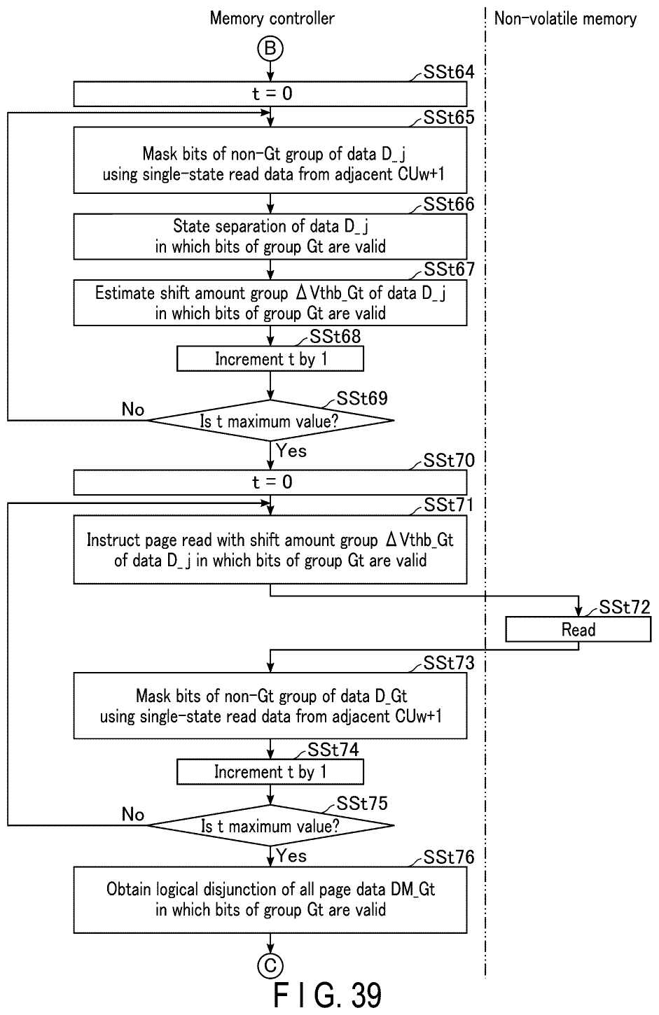

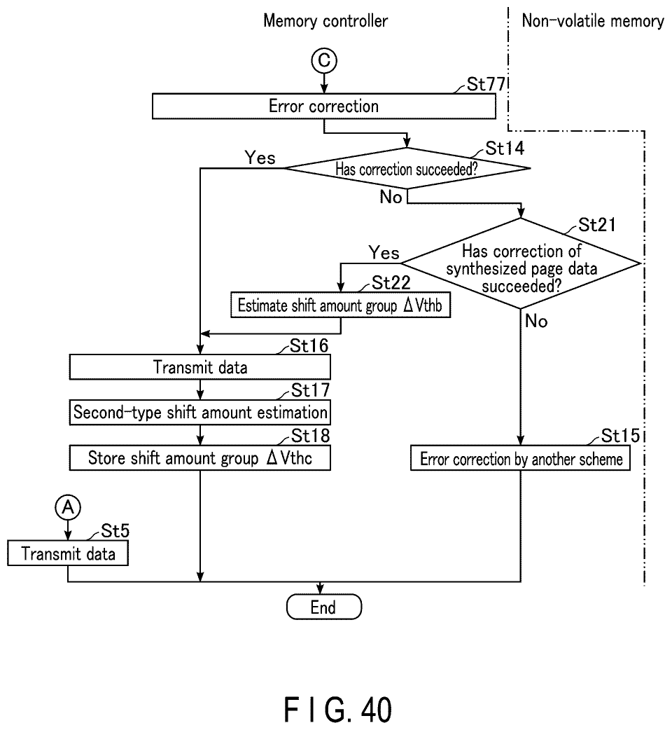

FIGS. 38 to 40 illustrate a flow of an operation of the memory system according to the fourth embodiment. The flow of FIGS. 38 to 40 is similar to the flow of FIG. 6, and is started if a data read request is received from the host device 2 and a selected page of a select cell unit CUw from which data is read is specified.

As illustrated in FIGS. 38 to 40, if the error correction fails (St4; No), the memory controller 10 instructs the nonvolatile memory 20 to perform a single-state read for acquisition of data for group classification (SSt61). Specifically, a single-state read of an adjacent cell unit CUw+1 using a read voltage Vu is instructed. If a shift amount is added to the read voltage Vu, the shift amount may be included in the instruction.

Upon receiving the instruction, the nonvolatile memory 20 performs a single-state read of the adjacent cell unit CUw+1 using the read voltage Vu (SSt62). The nonvolatile memory 20 transmits the obtained single-state read data DuR_w+1 to the memory controller 10. The memory controller 10 stores the received data DuR_w+1 in the single-state read data storage unit 36.

Step SSt62 follows step SSt1. The set of steps SSt1 and SSt2 may be performed prior to the set of steps SSt61 and SSt62.

If j is the maximum value (SSt7; Yes), the memory controller 10 sets 0 to t (SSt64).

The memory controller 10 masks the page data D_j using the single-state read data DuR_w+1 with respect to each of the cases where j takes one of 0 to 4 (SSt65). In the masking, bits of a group of data D_j other than bits of a group Gt (or, a non-Gt group) are masked. Through the masking, data DM_Gt_j is generated from the data D_j with respect to each of the cases where j takes one of 0 to 4.

The memory controller 10 performs state separation of the data DM_Gt_j with respect to each of the cases where j takes one of 0 to 4 (SSt66). Thereby, data DM_Gt_Sp_j is generated with respect to each of the cases where p takes all possible values based on the selected page and with respect to each of the cases where j takes one of 0 to 4. The data DM_Gt_Sp_j contains information of part of the data DM_Gt_j that is based on a read with a read voltage Vp where p denotes a value based on the selected page (e.g., a read voltage Vp1), and does not contain information of part of the data DM_Gt_j that is based on a read with a read voltage Vp where p denotes another value (e.g., a read voltage Vp2, etc.).

Step SSt66 may be performed prior to step SSt65.

The memory controller 10 estimates a shift amount group ΔVthb_Gt using the data DM_Gt_Sp_j with respect to all the cases where p takes all possible values based on the selected page (SSt67). The shift amount group ΔVthb_Gt is a shift amount group ΔVthb in the case of bits that belong to the group Gt. Estimation of the shift amount group ΔVthb_Gt is the same as the first-type shift amount estimation (step SSt9), except for the difference in the data used. That is, data DM_Gt Sp_j is used instead of the data DSp_j at step SSt9.

The memory controller 10 increments t by 1 (SSt68). The maximum value of t is equal to a value obtained by adding 1 to the number of groups. If t is not the maximum value (SSt69; No), the flow advances to step SSt65.

Steps SSt65, SSt66, and SSt67 may be performed while incrementing t from 0 by 1. That is, step SSt65 may be performed with respect to each of the cases where t denotes 0 and 1, step SSt66 may be performed with respect to each of the cases where t denotes 0 and 1, and step SSt67 may be performed with respect to each of the cases where t denotes 0 and 1.

If t is the maximum value (SSt69; Yes), this indicates that the shift amount group ΔVthb_Gt has been generated with respect to the cases of all the groups, namely, with respect to each of the cases where t denotes all possible values. The memory controller 10 sets 0 to the variable t again (SSt70).

The memory controller 10 instructs the nonvolatile memory 20 to read data from the selected page using the shift amount group ΔVthb_Gt (SSt71).

Upon receiving the instruction, the nonvolatile memory 20 reads data from the selected page using the shift amount group ΔVthb_Gt (SSt72). The nonvolatile memory 20 transmits the obtained page data D_Gt to the memory controller 10.

The memory controller 10 masks the page data D_Gt using the single-state read data DuR_w+1 for group classification (SSt73). Through the masking, data DM_Gt is acquired. The data DM_Gt has a version of the data D_Gt that contains valid data in bits that belong to the group Gt. In one example, the masking is performed by an AND operation of the data D_Gt and the data DuR_w+1.

The memory controller 10 increments t by 1 (SSt74). If t is not the maximum value (SSt75; No), the flow advances to step SSt71.

If t is the maximum value (SSt75; Yes), this indicates that the data DM_Gt has been generated with respect to the cases of all the groups, namely, with respect to each of the cases where t takes all possible values. The memory controller 10 generates a logical disjunction of data DM_Gt with respect to the cases of all the groups, namely, with respect to each of the cases where t denotes all possible values (SSt76). Thereby, data Db2, from which the effect of the state of an adjacent cell transistor MTw+1 on the state of the select cell transistor MTw is eliminated, is generated.

The memory controller 10 attempts to correct an error in the data Db2 using the error correction unit 34 (SSt77). Step SSt77 follows step St14.

Through the generation of the synthesized page data at step St21, p×t valid data portion groups DEGSp_Gt are generated with respect to each of the cases where p takes all possible values and where t takes all possible values. The valid data portion group DEGSp_Gt is a valid data portion group DEGSp in the case of bits that belong to the group Gt. The valid data portion group DEGSp_Gt is formed of five valid data portions DESp_Gt_0, DESp_Gt_1, DESp_Gt_2, DESp_Gt_3, and DESp_Gt_4. A single element DS_J is generated from the valid data portion DESp_Gt_0, DESp_Gt_1, DESp_Gt_2, DESp_Gt_3, or DESp_Gt_4 of each of the p×t valid data portion groups DEGSp_Gt. Accordingly, the Cartesian product is formed of a combination of all possible values for each of the parameters, assuming a case where the elements of an array of all the combinations of p and t (i.e., (p1_G1, p1_G2, . . . , p2_G1, p1_G2, . . . , p3_G1, and . . . )) are parameters and each of the parameters includes five valid data portions DESp_j. Thereafter, priorities h are then given to all the elements of the Cartesian product.

### 4.3. Advantages

According to the fourth embodiment, it is possible to provide a memory system 3 that reads data with high precision, as described below.

The threshold voltage of a cell transistor MT may be affected by the threshold voltage of an adjacent cell transistor MT into which data has been written after a write of data to the cell transistor MT. That is, if a state of a first cell transistor MT is shifted by a data write and then a threshold voltage of a second cell transistor MT adjacent thereto is raised by a data write, a state equivalent to a state in which the threshold voltage of the first cell transistor MT is raised by the threshold voltage of the second cell transistor MT is generated. Thereby, the state of the first cell transistor MT might be falsely determined.

According to the fourth embodiment, a shift amount group ΔVthb_Gt is estimated for each group into which a selected cell transistor MT has been classified based on the state of an adjacent cell transistor MTw+1. Data is then generated by a logical disjunction of page data obtained using the shift amount group ΔVthb_Gt. Since the data thus generated in each bit is based on a result of use of a shift amount based on the effect of the adjacent cell transistor MTw+1, such data is highly likely to succeed in an error correction. Accordingly, the error-corrected data Dc can be obtained with high probability. In addition, if the error correction succeeds, a shift amount group ΔVthc is estimated based on synthesized page data, similarly to the third embodiment. It is thus possible to achieve the same advantages as those achieved by the third embodiment.

### 4.4. Modifications

### 4.4.1. First Modification

The memory controller 10 may acquire a shift amount ΔVp_G2, which is for case of t being 2, namely, where the bits of the second group are valid, based on the shift amount ΔVp_G1 in the case where the bits of the first group are valid. That is, the relationship between the shift amount ΔVp_G1 and the shift amount ΔVp_G2 is known in advance by the memory controller 10 by a correspondence table generated by a mathematical expression or an in-advance evaluation. The memory controller 10 acquires the shift amount ΔVp_G2 using the relationship and the shift amount ΔVp_G1.

### 4. 4. 2. Second Modification

In a second modification, each bit of page data D_j_w is classified into one of a first group, a second group, and a third group. The classification into the first, second, and third groups is performed based on the state of an adjacent cell transistor MTw+1. The first group includes bits of a selected cell transistor MTw adjacent to an adjacent cell transistor MTw+1 in a lower state than the “Su” state. The second group includes bits of a selected cell transistor MTw adjacent to an adjacent cell transistor MTw+1 in the “Su” state or a state higher than the “Su” state and lower than the “Sv” state. Here, v is either 0 or a positive integer. The third group includes bits of a selected cell transistor MTw adjacent to an adjacent cell transistor MTw+1 in the “Sv” state or a higher state.

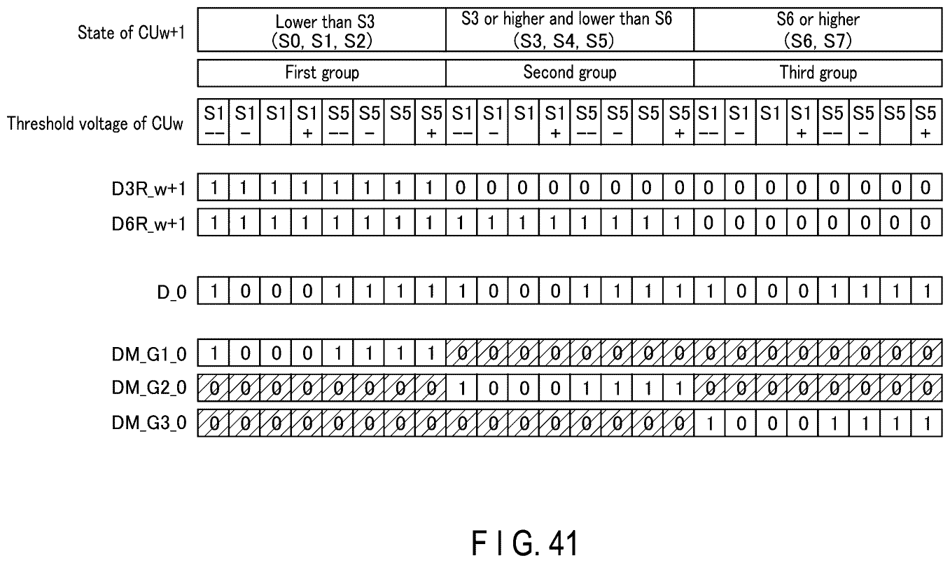

FIG. 41 illustrates a concept of a first-type shift amount estimation by a memory system according to a second modification of the fourth embodiment. In FIG. 41, a lower page is illustrated as a representative. In an example, u is 3, and v is 6. Whether the adjacent cell transistor MTw+1 belongs to a set of states lower than the “S3” state, a set of the “S3” state and states higher than the “S3” state and lower than the “S6” state, or a set of the “S6” state and higher states than the “S6” state can be known from the data D3R_w+1 and D6R_w+1.

For classification into the first, second, or third group, the page data D_j_w is masked by data D3R_w+1 and D6R_w+1 with respect to each of the cases where j takes one of 0 to 4. Through the masking, data DM_G1_j, DM_G2_j, and DM_G3_j are generated with respect to each of the cases where j takes one of 0 to 4.

The memory controller 10 instructs, at step SSt61, a single-state read of the adjacent cell unit CUw+1 with a read voltage Vu, and a single-state read of the adjacent cell unit CUw+1 with a read voltage Vv. In the second modification, the maximum value of t is 3.

### 4. 4. 3. Third Modification

In a third modification, each bit of page data D_j_w is classified into one of a first group, a second group, a third group, and a fourth group. The classification into the first, second, third, and fourth groups is performed based on a combination of the state of an adjacent cell transistor MTw+1 and the state of an adjacent cell transistor MTw−1. The adjacent cell transistor MTw−1 is coupled to a conductor CW adjacent to a conductor CW (word line WL) coupled to a select cell unit CUw on the negative side of the z-axis.

The first group includes bits of a select cell transistor MTw adjacent to an adjacent cell transistor MTw+1 in a lower state than the “Su” state and an adjacent cell transistor MTw−1 in a lower state than the “Su” state.

The second group includes bits of a select cell transistor MTw adjacent to an adjacent cell transistor MTw+1 in a lower state than the “Su” state and an adjacent cell transistor MTw−1 in the “Su” state or a higher state.

The third group includes bits of a select cell transistor MTw adjacent to an adjacent cell transistor MTw+1 in the “Su” state or a higher state and an adjacent cell transistor MTw−1 in a lower state than the “Su” state.

The fourth group includes bits of a select cell transistor MTw adjacent to an adjacent cell transistor MTw+1 in the “Su” state or a higher state and an adjacent cell transistor MTw−1 in the “Su” state or a higher state.

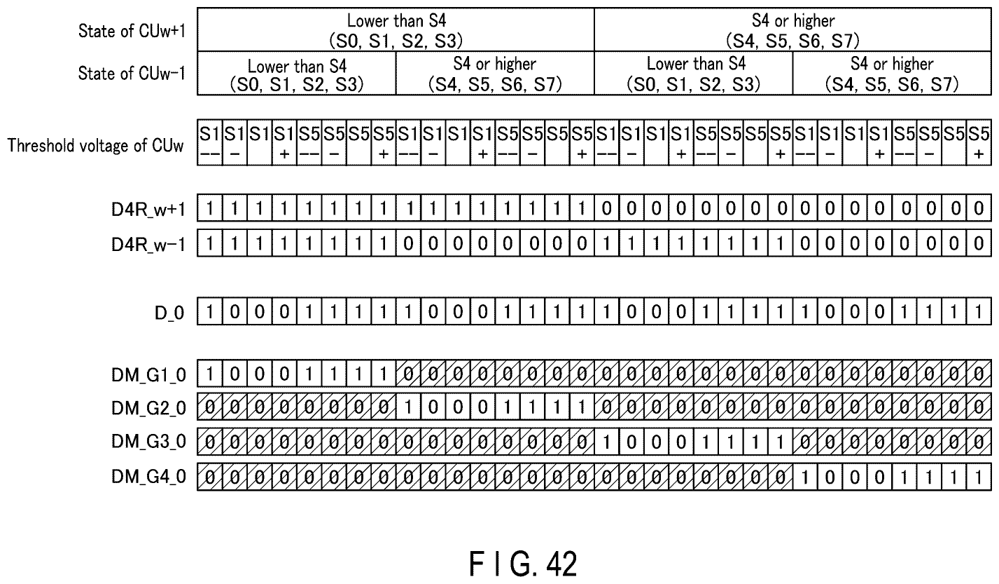

FIG. 42 illustrates a concept of a first-type shift amount estimation by a memory system according to a third modification of the fourth embodiment. In FIG. 42, a lower page is illustrated as a representative. In an example, u is 4. Whether the adjacent cell transistor MTw−1 is in a lower state than the “S4” state or in the “S4” state or a higher state can be known from single-state read data D4R_w−1.

For classification into the first, second, third, or fourth group, the page data D_j_w is masked by data D4R_w+1 and D4R_w−1, with respect to each of the cases where j takes one of 0 to 4. Through the masking, data DM_G1_j, DM_G2_j, DM_G3_j, and DM_G4_j are generated with respect to each of the cases where j takes one of 0 to 4.

The memory controller 10 instructs, at step SSt61, a single-state read of the adjacent cell unit CUw+1 with a read voltage Vu, and a single-state read of the adjacent cell unit CUw−1 with a read voltage Vu. In the third modification, the maximum value of t is 4.

### 4. 4. 4. Fourth Modification

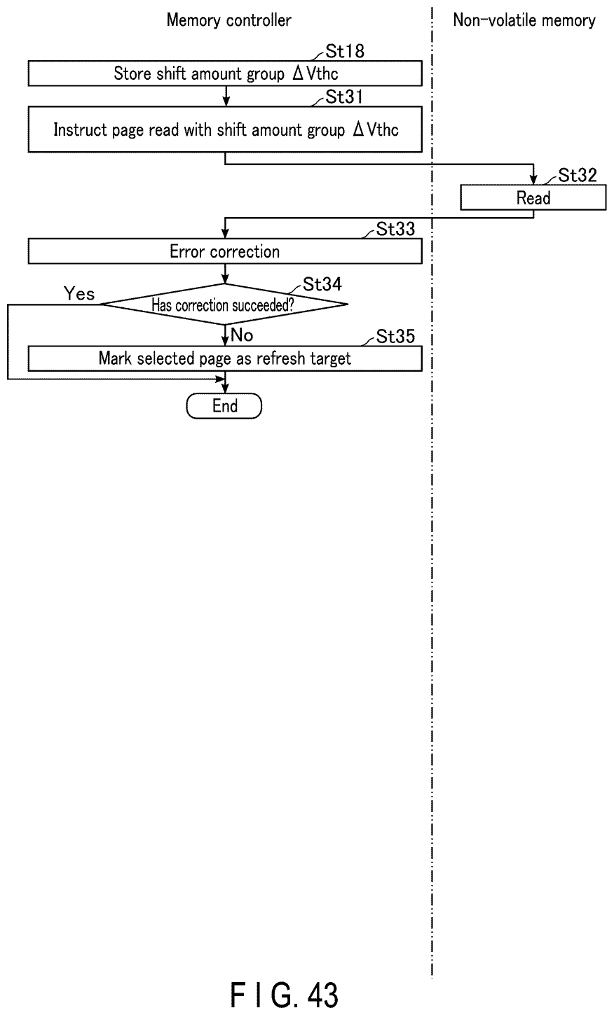

FIG. 43 illustrates a flow of an operation of a memory system according to a fourth modification of the fourth embodiment. The flow of the fourth embodiment includes additional steps after step St18 in the flow of the basic aspect (illustrated in FIGS. 38 to 40) of the fourth embodiment.

As illustrated in FIG. 43, step St18 follows step St31. The memory controller 10 instructs the nonvolatile memory 20 to read data from the selected page using a shift amount group ΔVthc (St31).

Upon receiving the instruction, the nonvolatile memory 20 reads data Dd from the selected page using the shift amount group ΔVthc (St32). The nonvolatile memory 20 transmits the read data Dd to the memory controller 10.

Upon receiving the data Dd, the memory controller 10 attempts to correct an error in the data Dd using the error correction unit 34 (St33).

If the error correction succeeds (St34; Yes), this indicates confirmation that the use of the shift amount group ΔVthc leads to a read of data Dd that leads to success in the error correction. Thus, by using the shift amount group ΔVthc in the next read of data from the selected page, it can be expected that data Dd that is likely to result in success in error correction is read. Through the success in the error correction, the flow ends.

If the error correction fails (St34; No), this indicates confirmation that the error correction of the data Dd obtained using the shift amount group ΔVthc will not succeed, even though the shift amount group ΔVthc has been estimated based on the synthesized page data DT for which error correction has succeeded. Accordingly, the memory controller 10 marks the selected page as a refresh target (St35). A refresh is a process autonomously performed by the memory system 3 while the memory system 3 is not performing a process based on a request from the host device 2. Through the refresh, the memory system 3 reads data of a refresh target page, performs error correction of the read data by an advanced method, and writes the error-corrected data into the nonvolatile memory 20 as data of a refresh target page.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
a non-volatile memory including a plurality of memory cells; and
a memory controller configured to:
store first data read from the plurality of memory cells in a storage circuit, the first data being read by using a first voltage;
store second data read from a bit group including respective bits of the plurality of memory cells in a storage circuit, the second data being read by using a first read voltage group;
perform an error correction of the second data; and
determine, if third data is obtained as a result of successful error correction of the second data, a second read voltage group based on the first data stored in the storage circuit, the second data, and the third data.

2. The memory system according to claim 1, wherein
the memory controller is configured to determine the second read voltage group based on a first count and a second count of the second data based on comparison between the second data and the third data,
the first count is a count of first bits of the third data in which a first-type error has been corrected, and
the second count is a count of second bits of the third data in which a second-type error has been corrected.

3. The memory system according to claim 2, wherein
the first bits are bits that has a first value in the second data and has a second value in the third data, and
the second bits are bits that has the second value in the second data and has the first value in the third data.

4. The memory system according to claim 3, wherein
the memory controller determines the second read voltage group based on a voltage that makes a ratio between the first count and the second count close to 1.

5. The memory system according to claim 2, wherein
the second read voltage group includes a first read voltage and a second read voltage, and
the memory controller is configured to:
acquire, based on the first data stored in the storage circuit, the second data, and the third data, a third count of the first bits of the third data, a fourth count of the first bits of the third data, a fifth count of the second bits of the third data, and a sixth count of the second bits of the third data;
determine the first read voltage based on the third count and the fifth count; and
determine the second read voltage based on the fourth count and the sixth count.

6. The memory system according to claim 1, wherein
the first read voltage group includes a third read voltage and a fourth read voltage, and
the memory controller is configured to:
store a plurality of items of fourth data read from the bit group in a storage circuit, the plurality of items of fourth data being read using a plurality of third read voltage groups;
generate a plurality of items of fifth data and a plurality of items of sixth data from the plurality of items of fourth data using the first data;
determine the third read voltage based on the plurality of items of fifth data; and
determine the fourth read voltage based on the plurality of items of sixth data.

7. The memory system according to claim 1, wherein
the non-volatile memory further includes a word line coupled to the plurality of memory cells,
the non-volatile memory is configured to read the first data by applying the first read voltage and to send the first data to the memory controller, and
the memory controller is configured to acquire the first data by receiving the first data.

8. The memory system according to claim 6, wherein
the non-volatile memory further includes a word line coupled to the plurality of memory cells,
the non-volatile memory is configured to read the second data by applying the third read voltage and the fourth read voltage and to send the second data to the memory controller, and
the memory controller is configured to acquire the second data by receiving the second data.

9. A memory system, comprising:
a non-volatile memory including a plurality of memory cells;
a memory controller configured to:
store a plurality of items of first data read from a bit group including respective bits of the plurality of memory cells in a storage unit, the plurality of items of first data being read using a plurality of different first read voltage groups;
determine a second read voltage group using the plurality of items of first data;
store second data read from the bit group in a storage circuit, the second data being read using the second read voltage group;
acquire, if third data is obtained as a result of error correction of the second data, a plurality of first counts and a plurality of second counts based on the plurality of items of first data and the third data; and
determine a third read voltage group based on comparison between the plurality of first counts and the plurality of second counts.

10. The memory system according to claim 9, wherein
the plurality of first counts have a first relationship that has a distribution for magnitudes of read voltages used in the read from the bit group,
the plurality of second counts have a second relationship that has a distribution for magnitudes of read voltages used in the read from the bit group,
each of the plurality of first counts is a count of first bits of one of the plurality of items of first data in which a first-type error has been corrected,
each of the plurality of second counts is a count of second bits of one of the plurality of items of first data in which a second-type error has been corrected, and
the memory controller determines the third read voltage group based on the first relationship and the second relationship.

11. The memory system according to claim 10, wherein
the first bits are bits that has a first value in the second data and has a second value in the third data, and
the second bits are bits that has the second value in the second data and has the first value in the third data.

12. The memory system according to claim 11, wherein
the second read voltage group includes a first read voltage and a second read voltage,
the third read voltage group includes a third read voltage and a fourth read voltage,
the memory controller is configured to:
store fourth data read from the plurality of memory cells in a storage unit, the fourth data being read using a first voltage;
generate a plurality of items of fifth data and a plurality of items of sixth data from the plurality of items of first data using the fourth data;
determine the first read voltage based on the plurality of items of fifth data;
determine the second read voltage based on the plurality of items of sixth data; and
generate a plurality of items of seventh data and a plurality of items of eighth data from the plurality of items of first data, the third data, and the fourth data, wherein
each of the plurality of first counts is a count of first bits of one of the plurality of items of seventh data, and
each of the plurality of second counts is a count of second bits of one of the plurality of items of eighth data.

13. The memory system according to claim 12, further comprising:
a first storage circuit configured to store the plurality of items of first data up to an intermediate stage of the generating of the plurality of items of seventh data and the plurality of items of eighth data; and
a second storage circuit configured to store the fourth data until completion of the generating of the plurality of items of seventh data and the plurality of items of eighth data.

14. The memory system according to claim 9, wherein
the second read voltage group includes a first read voltage and a second read voltage,
the third read voltage group includes a third read voltage and a fourth read voltage,
the memory controller is configured to:
store fourth data read from the plurality of memory cells in a storage circuit, the fourth data being read using a first voltage;
generate a plurality of items of fifth data and a plurality of items of sixth data from the plurality of items of first data using the fourth data;
determine the first read voltage based on the plurality of items of fifth data;
determine the second read voltage based on the plurality of items of sixth data;
generate a plurality of items of ninth data and a plurality of items of tenth data based on the third data and the plurality of items of fifth data; and
generate a plurality of items of eleventh data and a plurality of items of twelfth data based on the third data and the plurality of items of sixth data,
each of the plurality of first counts is a count of bits of one of the plurality of items of ninth data and the plurality of items of eleventh data in which a first-type error has been corrected, and
each of the plurality of second counts is a count of bits of one of the plurality of items of tenth data and the plurality of items of twelfth data in which a second-type error has been corrected.

15. A memory system, comprising:
a non-volatile memory including a plurality of memory cells; and
a memory controller configured to:
store a plurality of items of first data read from a bit group including respective bits of the plurality of memory cells in a storage circuit, the plurality of items of first data being read using a plurality of first read voltage groups;
determine a second read voltage group using the plurality of items of first data;
store second data read from the bit group in a storage circuit, the second data being read using the second read voltage group; and
perform, if error correction of the second data fails, an error correction of fifth data including a first portion of third data of one of the plurality of items of first data and a second portion of fourth data of one of the plurality of items of first data, wherein
the third data and the fourth data differ from each other, and the first portion and the second portion differ from each other.

16. The memory system according to claim 15, wherein
the first portion of the third data includes a plurality of bits of one of the plurality of items of first data classified into a first group based on a first standard,
the second portion of the fourth data includes a plurality of bits of one of the plurality of items of first data classified into a second group based on the first standard, and
the first group and the second group differ from each other.

17. The memory system according to claim 16, wherein
the memory controller is configured to store sixth data read from the plurality of memory cells in a storage circuit, the sixth data being read using a first voltage,
the first portion of the third data includes a plurality of bits classified into the first group based on one of the plurality of items of first data and the sixth data, and
the second portion of the fourth data includes a plurality of bits classified into the second group based on one of the plurality of items of first data and the sixth data.

18. The memory system according to claim 17, wherein
the plurality of bits classified into the first group contain data based on one of the plurality of memory cells determined to have a threshold voltage lower than the first voltage, and
the plurality of bits classified into the second group contain data based on one of the plurality of memory cells determined to have a threshold voltage equal to or higher than the first voltage.

19. The memory system according to claim 15, wherein
the non-volatile memory further includes a plurality of second memory cells,
the memory controller is configured to store seventh data read from the plurality of second memory cells in a storage circuit, the seventh data being read using a second voltage,
the first portion of the third data includes, from one of the plurality of items of first data, a plurality of bits classified into a first group based on the seventh data, and
the second portion of the fourth data includes, from one of the plurality of items of first data, a plurality of bits classified into a second group based on the seventh data.

20. The memory system according to claim 18, wherein
the plurality of bits classified into the first group contain data based on one of the plurality of memory cells adjacent to one of the plurality of second memory cells determined to have a threshold voltage lower than the second voltage, and
the plurality of bits classified into the second group contain data based on one of the plurality of memory cells determined to have a threshold voltage equal to or higher than the second voltage.
